(19) United States
(12) Patent Application Publication
(10) Pub. No.: US 2012/0234369 A1
(43) Pub. Date: Sep. 20, 2012

(54) SOLAR CELL INTERCONNECTION PROCESS

(75) Inventors: Vernie Allan Everett, Kaleen (AU); Andrew William Blakers, Aranda (AU); Klaus Johannes Weber, Aranda (AU)

(73) Assignee: Transform Solar Pty Ltd

(21) Appl. No.: 13/427,347

(22) Filed: Mar. 22, 2012

Related U.S. Application Data
(63) Continuation of application No. 11/922,275, filed on Oct. 28, 2008, now abandoned.

(30) Foreign Application Priority Data
Jun. 17, 2005 (AU) 2005903172

(51) Int. Cl. H01L 31/18; H01L 31/05

(52) U.S. Cl. 136/244; 438/67; 257/E31.113

(57) ABSTRACT

A solar cell interconnection process for forming a solar cell sub-module for a photovoltaic device, the process including the steps of mounting a plurality of elongate solar cells (101) on a crossbeam (102) on patches of solderable material (201) which is used to maintain solder in position, the elongate solar cells being in a substantially longitudinally parallel and generally co-planar configuration: and establishing one or more conductive pathways (204) extending between adjacent cells to electrically interconnect the elongate solar cells via the contacts (202, 203): wherein the one or more conductive pathways are established by wave soldering.

### RELATED APPLICATIONS

This application is a continuation of U.S. application Ser. No. 11/922,275, filed Jun. 16, 2006, the entire teachings of which are incorporated herein by reference, and which itself is a U.S. National Stage application of International Application No. PCT/AU2006/000840, filed on Jun. 16, 2006, published in English, which claims priority under 35 U.S.C. §119 or 365 to Australia, Application No. AU 2005903172, filed Jun. 17, 2005.

### FIELD

The present invention relates to a solar cell interconnection process for interconnecting elongate solar cells to form a solar cell sub-module for a photovoltaic device.

### BACKGROUND

In this specification, the term “elongate solar cell” refers to a solar cell of generally parallelepiped form and having a high aspect ratio in that its length l is substantially greater (typically some tens to hundreds of times larger) than its width w. Additionally, this width of an elongate solar cell is substantially greater (typically four to one hundred times larger) than its thickness t. The length and width of a solar cell define the maximum available active or useable surface area for power generation (the active “face” or “faces” of the solar cell), whereas the length and thickness of a solar cell define the optically inactive surfaces or “edges” of a cell. A typical elongate solar cell is 10-120 mm long, 0.5-5 mm wide, and 15-400 microns thick.

Elongate solar cells can be produced by processes such as those described in “HighVo (High Voltage) Cell Concept” by S. Scheibenstock, S. Keller, P. Fath, G. Willeke and E. Bucher, Solar Energy Materials & Solar Cells Vol. 65 (2001), pages 179-184 (“Scheibenstock”), and in International Patent Application Publication No. WO 02/45143 (“the Sliver patent application”). The latter document describes processes for producing a large number of thin (generally <150 μm) elongate silicon substrates from a single standard silicon wafer where the number and dimensions of the resulting thin elongate substrates are such that the total useable surface area is greater than that of the original silicon wafer. This is achieved by using at least one of the new formed surfaces perpendicular to the original wafer surfaces as the active or useable surface of each elongate substrate, and selecting the shorter dimensions in the wafer plane of both the resulting elongate substrates and the material removed between these substrates to be as small as practical, as described below.

Such elongate substrates are also referred to as ‘sliver substrates’. The word “SLIVER” is a registered trademark of Origin Energy Solar Pty Ltd, Australian Registration No. 933476. The Sliver patent application also describes processes for forming solar cells on sliver substrates, referred to as ‘sliver solar cells’. However, the word ‘sliver’ generally refers to a sliver substrate which may or may not incorporate one or more solar cells.

In general, elongate solar cells can be single-crystal solar cells or multi-crystalline solar cells formed on elongate substrates using essentially any solar cell manufacturing process. As shown in FIG. 18, elongate substrates are preferably formed in a batch process by machining (preferably by anisotropic wet chemical etching) a series of parallel elongate rectangular slots or openings 1802 completely through a silicon wafer 1804 to define a corresponding series of parallel elongate parallelepiped substrates or ‘slivers’ 1806 of silicon between the openings 1802. The length of the slots 1802 is less than, but similar to, the diameter of the wafer 1804 so that the elongate substrates or slivers 1806 remain joined together by the remaining peripheral portion 1808 of the wafer, referred to as the wafer frame 1808. Each sliver 1806 is considered to have two edges 1810 coplanar with the two wafer surfaces, two (newly formed) faces 1812 perpendicular to the wafer surface, and two ends 1814 attached to the wafer frame 1808. As shown in FIG. 18, solar cells can be formed from the elongate substrates 1806 while they remain retained by the wafer frame 1808; the resulting elongate solar cells 1806 can then be separated from each other and from the wafer frame to provide a set of individual elongate solar cells, typically with electrodes along their long edges. A large number of these elongate solar cells can be electrically interconnected and assembled together to form a solar power module.

When elongate substrates are formed in this way, the width of the elongate slots and the elongate silicon strips (slivers) in the plane of the wafer surface are both typically 0.05 mm, so that each sliver/slot pair effectively consumes a surface area of l×0.1 mm from the wafer surface, where l is the length of the elongate substrate. However, because the thickness of the silicon wafer is typically 0.5-2 mm, the surface area of each of the two newly formed faces of the sliver (perpendicular to the wafer surface) is l×0.5-2 mm, thus providing an increase in useable surface area by a factor of 5-20 relative to the original wafer surface (neglecting any useable surface area of the wafer frame).

Elongate substrates can also be formed by dividing a wafer into a plurality of substrates in a manner generally similar to that described above, but where the active or useable surfaces of the resulting elongate substrates are corresponding elongate portions of the original wafer surface or surfaces. Such elongate substrates have a thickness equal to that of the wafer from which they were formed, and are referred to herein as ‘plank’ substrates. In this case, the total useable surface area of the plank substrates cannot be greater than that of the original wafer; however, plank solar cells formed from plank substrates nevertheless have advantages over conventional, wafer-based solar cells. A plank solar cell typically has electrodes along its long edges, but may alternatively have electrodes of opposing polarities on one of its faces (to be oriented away from the sun when in use).

The elongate slices of silicon that form sliver solar cells are fragile and need careful handling in relation to mounting and electrical interconnection. Additionally, since the surface area and economic value of each sliver cell is small, a reliable low cost electrical connection technique is required in order to make the use of sliver cells economically viable.

Prior art approaches to using sliver solar cells to form photovoltaic devices have involved gluing the cells to a substrate or transparent superstate such as glass using an optical adhesive to form a large array of the sliver solar cells. The sliver solar cells have a regular spacing between adjacent cells ranging from zero to several millimeters, and may contain anywhere from around one thousand sliver solar cells up to as many as fifteen thousand sliver solar cells per square metre of module area, depending on the particular cell and module configuration. A “pick and place” robotic machine can be used to position the sliver solar cells on the substrate. The cells are then electrically interconnected using a conductive epoxy which is stencilled, dispensed or otherwise transferred to form electrical interconnections between sliver cells.

Alternatively, sliver cells which have been bonded to a substrate such as glass are electrically inter-connected by reflowing solder paste which has been stencilled or dispensed onto metallised pads or tracks previously prepared on the glass substrate. This process for establishing electrical inter-connections between slivers bonded to a substrate glass requires several precision steps to prepare the metallised track array, dispense or stencil the solder paste onto the prepared metallised tracks with sufficient accuracy in respect to alignment, paste volume, and paste distribution, and then to reflow the solder paste by heating the entire assembly above the solder liquidus temperature and with the required temperature-time profile necessary for flux activation, solder flow, and the formation of inter-metallic alloys necessary for suitable wetting of the metallised tracks and the sliver cell metal electrodes, and for the solder to flow to the correct bulk-distribution determined by the solder surface tension and wetting properties.

Although dispensing of conductive material is a scalable alternative, able to accommodate any module size, as opposed to stencil application where the area is limited by stencil and alignment accuracy properties, the dispensing operation is slow and expensive for the number of dispense sites required over a large module area. Stencilling has problems with alignment and registration of the stencil sites over a large area because of stretch and warpage of the stencil material. Furthermore, heating a large thermal mass in an in-line or batch process with the temperature-time profiles required for good solder joints using a solder reflow operation causes practically insurmountable difficulties, including problems with silver dissolution from the sliver electrodes because of the time required above liquidus, the difficulty of rapidly cooling the glass to form small crystal structure in the bulk solder, minimising alloy separation and metal migration in the solder interconnects, and possible damage to the UV-curable optical adhesive under high temperature for extended periods. Some of the above reflow problems can be solved using a vapour phase solder system such as an Asscon Quicky® vapour-phase reflow system, but the remaining problems make a reflow operation unsuitable for commercially viable module production.

Irrespective of which of the above methods is used, an encapsulation material such as EVA is then used together with a second layer of glass or similar material to complete the assembly of a solar cell array and form a solar module. The most significant difficulty with forming a photovoltaic device using this technique is the requirement for precise placement, using stencilling or dispensing, of conductive material—regardless of whether that material is solder or some form of conductive epoxy or similar material, to form the electrical interconnections between a large number of sliver cells over a relatively large area of substrate in order to form the array.

Plank solar cells are formed from multi-crystalline silicon or single crystal silicon. The solar cells are manufactured using a conventional cell fabrication process, with some variations similar to the well-known BCSC process. The primary advantage of plank and plank-like solar cells is to build voltage, and consequently as an associated effect to reduce current, more rapidly than is possible with conventional cells. Furthermore, in one implementation of plank solar cells, the cells so formed are bifacial. The benefits of bifacial solar cells offset the extra cost of producing, handling, and assembling plank cells through plank cell applications in bifacial modules, building integrated photovoltaic modules (BIPV), static concentrator assemblies, and also applications in concentrator receivers with solar concentrations up to 30 times, or 50 times, or even more, normal solar radiation.

The thick, that is, standard wafer thickness, relatively narrow rectangular array of plank cells formed in the wafer can be produced in a form suitable for use as stand-alone solar cells when removed from the wafer, or alternatively in a form suitable to be contained in the wafer in which they were formed with the areas of silicon at each end of the cells forming the physical retention structure which also provides a high-resistance path for the current formed in the cells. One form of monolithic plank-type cells is discussed in the paper “Progress in monolithic series connection of wafer-based crystalline silicon solar cells by the novel ‘High Vo’(High Voltage) cell concept”, in the journal Solar Energy Materials & Solar Cells 65 (2001) pp 179-184. Alternatively, the plank solar cells can be removed from the wafer and re-assembled with any desired spacing and/or cell polarities. Although plank cells are not as fragile as sliver cells, they nevertheless require careful handling during mounting or electrical interconnection. Additionally, since the area and value of each cell is small, a reliable low cost electrical connection technique is required in order to make the use of plank cells economically viable.

Because the active faces of plank cells are formed from the polished wafer surface, handling and assembly is significantly more straightforward than sliver cell handling and assembly, where the active slow cell faces are formed perpendicular to the wafer surface. If the plank cell array is intended for maximum efficiency applications, the entire array of plank cells can be removed from the wafer by engaging the array with a vacuum device, adhesive surface, or a mechanical clamp. The array is released from the wafer frame by cutting the ends of the plank cells with a dicing saw, or a laser, or by mechanical scribing and fracture. The electrical interconnections are then established using a process similar to that required to form sliver cell boat assemblies, a process which also provides the physical structure of the plank solar cell boat.

The distinctive features of the plank boat sub-module assembly include a close-packed planar or near-planar array of rectangular or near-rectangular solar cells of dimensions similar to a conventional square or near-square solar cell, a sub-module voltage proportionately higher than a conventional cell by a factor similar to the number of plank cells contained in the unit assembly, a sub-module current proportionately lower than a conventional cell by a factor similar to the number of plank cells contained in the unit assembly, and electrical contacts suitable for external interconnections such as stringing the plank boats together to form structures which can be included in plank boat solar cell power modules.

Alternatively, if the plank cell array is intended to provide increased cost-efficiency applications, the entire array of plank cells may be removed from the wafer by engaging the array with a vacuum device or an adhesive surface, or a mechanical clamp. The array is released from the wafer frame by cutting the ends of the plank cells with a dicing saw, or a laser, or by mechanical scribing and fracture. If the planks cells are required for a 2× static concentrator, for example, the plank cell array is then manipulated using a simple vacuum system that picks up every second plank cell, forming a double-spaced array from the picked up cells, and leaving a double-spaced array formed by the cells bypassed by the initial pick-up operation. Both these double-spaced arrays are then processed to establish electrical inter-connections and form the physical retention structure of plank raft sub-assemblies in a process similar to sliver raft formation. The electrical interconnections are then established, a process which also provides the physical structure of the plank solar cell raft. A 3× static concentrator sub-assembly can be formed simply by selecting every third plank solar cell in two steps, and completing three sub-assemblies, for example.

The distinctive features of the plank raft sub-module assembly include a uniformly-spaced planar or near-planar array of rectangular or near-rectangular solar cells of dimensions similar to a conventional square or near-square solar cell, a sub-module voltage proportionately higher than a conventional cell by a factor similar to the number of plank cells contained in the unit assembly, a sub-module current proportionately lower than a conventional cell by a factor similar to the number of plank cells contained in the unit assembly (in the absence of any static concentrator features, and this reduced current modified simply by any effective concentration factor gained from the static concentrator application), and electrical contacts suitable for external interconnections such as stringing the plank rafts together to form structures which can be included in a plank raft solar cell power module.

Similarly, if the plank cell array is intended to provide increased cost-efficiency applications, the entire array of plank cells may be removed from the wafer by engaging the array with a vacuum device or an adhesive surface, or a mechanical clamp. The array is released from the wafer frame by cutting the ends of the plank cells with a dicing saw, or a laser, or by mechanical scribing and fracture. If the planks cells are required for a 2× static concentrator, for example, the plank cell array is then manipulated using a simple vacuum system that picks up every second plank cell, forming a double-spaced array from the picked up cells, and leaving a double-spaced array formed by the cells bypassed by the initial pick-up operation. Both these double-spaced arrays, are then processed to establish electrical inter-connections and form the physical retention structure of plank mesh raft sub-assemblies in a process similar to sliver mesh raft formation. The electrical interconnections are then established, a process which also provides the physical structure of the plank solar cell mesh raft.

The distinctive features of the plank mesh raft sub-module assembly include a uniformly-spaced planar or near-planar array of rectangular or near-rectangular solar cells of dimensions similar to a conventional square or near-square solar cell, flexibility around the axis running parallel to the length of the plank solar cells provided solely by the flexibility in the wire interconnections, a sub-module voltage proportionately higher than a conventional cell by a factor similar to the number of plank cells contained in the unit assembly, a sub-module mesh raft current proportionately lower than a conventional cell by a factor similar to the number of plank cells contained in the unit assembly (in the absence of any static concentrator features, and this reduced current modified simply by any effective concentration factor gained from the static concentrator application), and electrical contacts suitable for external interconnections such as stringing the plank mesh rafts together to form structures which can be included in a plank mesh raft solar cell power module.

Prior art approaches to using plank and plank-like solar cells to form photovoltaic devices have generally been limited to specialty applications such as the high voltage, small area solar power module for charging batteries in portable devices, or running small portable devices such as electronic calculators because of the relatively high cost of handling, assembling, and providing electrical connections and physical structure to plank and plank-like collections, assemblies, or arrays of relatively cheap, small solar cells. The approaches detailed in this invention that solve the problems associated with prior art approaches to handling, assembly, and electrical inter-connection of sliver solar cells have a direct, analogous application to solving the problems associated with the conventional handling, assembly, and electrical interconnection of plank and plank-like solar cells.

The same handling and assembly principles invoked for devising a solution to the sliver separation, handling, and assembly problem was applied to devising a solution to the plank cell separation, handling and assembly problem: bulk movement of “large” numbers of cells at all times, with regard to adapting conventional handling and assembly equipment and processes where possible. In most cases, the solution devised for separating, handling, and assembling plank solar cells involves at most a simple modification or customising of the sliver solution.

In general, in describing preferred embodiments of the present invention, references and illustrations will principally use sliver cell examples to clarify the advantageous aspects of the process and method. References and illustrations with respect to plank solar cell requirements will only be provided where the separation, handling, or assembly requirements are markedly or substantively different to the process and method for sliver solar cell separation, handling, and assembly solution.

One application of solar cells is in so-called concentrator systems. A typical linear photovoltaic concentrator system operates at a geometric cell concentration ratio of about 10 to 80 times. In such an arrangement a single line of solar cells is normally mounted on the receiver. Each conventional cell is typically 2 to 5 cm wide and 20 to 40 cells are connected in series along the longitudinal length of the receiver. The uniformity of the light is generally good along the length of the receiver but poor in the transverse direction. The solar cells are usually connected in series to provide a higher overall voltage output. Electrical current is typically conducted from the centre to the two edges of each cell on both upper and lower surfaces through four long contacts per cell. Connection is made to each of these contacts to remove the current. Series connection of the solar cells is achieved at the edge of the receiver by appropriate interconnection. However, the series interconnection occupies a significant area. Additionally, electrical current flow along the length of the receiver is a process of moving electrical charge transversely from the central region of each cell to the edge into the external connections and back to the central region of the neighbouring cell. As a consequence, significant series resistance losses arise because of the long conduction pathway.

It is desired to provide a solar cell interconnection process that alleviates one or more of the above difficulties, or to at least provide a useful alternative.

### SUMMARY

In accordance with the present invention, there is provided a solar cell interconnection process for forming a solar cell sub-module for a photovoltaic device, the process including the steps of:
mounting a plurality of elongate solar cells in a structure that maintains the elongate solar cells in a substantially longitudinally parallel and generally co-planar configuration; and
establishing one or more conductive pathways extending through the structure to electrically interconnect the elongate solar cells;
   wherein the one or more conductive pathways are established by wave soldering.

The mounting structures of the rafts, mesh rafts, or boats described herein prevent damage to the plank or sliver solar cells or electrical inter-connections resulting from thermal cycling during manufacture or use. In the case of boats, this is achieved by mounting the plank or sliver solar cells on a thermally compatible substrate and providing electrically conductive pathways, using conventional solders or lead-free solders in one or more of their many forms, that extend across the substrate in discrete patterns that provide a series or parallel configuration to establish the electrical interconnections. In the case of mesh rafts, and some forms of rafts, electrical interconnections between the plank cells or the sliver cells respectively form the mounting or framework structure so that the differential thermal expansion between the constituent materials in the mesh raft or raft or boat do not produce unacceptable stress in any part of the sub-module assembly structure.

The sliver solar cells or plank solar cells in each sub-module can be spaced according to requirements for the particular photovoltaic device. In some applications, such as boats, there may be no, or very little, spacing so that the adjacent slivers or planks, respectively, abut with the solder that provides not only the electrical interconnections, but also the mechanical support or constraint retaining the solar cells together in the case of boats, and/or with the solder forming the electrical interconnection also forming the mechanical structure which directly attaches the plank or sliver solar cell to the substrate in the case of high efficiency rafts or boats.

In other applications, such as rafts or mesh rafts, the spacing between each plank or sliver solar cell could be as much as several times the width of the solar cells, with the electrical interconnections between adjacent cells established by solder alloyed to a metallised track on the surface of a cross-beam. In other applications, such as mesh rafts, wires which form the structure of an inter-cell array are soldered to the plank or sliver cell electrodes to provide electrical interconnection as well as physical support and physical constraint of the mesh raft structure. In particular, the plank solar cells may be bifacial, and the sliver solar cells are bifacial, and in some applications the spacing is determined to take advantage of irradiation of both sides of the sliver solar cells by use of appropriately positioned reflectors in the case of static concentrator applications, or by illumination from both sides in the case of module structures resembling conventional bifacial modules.

In one embodiment the substrate takes the form of one or more cross-beams to which the sliver cells or plank cells are held in the desired array formation and in close proximity to the cross-beams using a mechanical jig. The cross-beams provide mechanical stability for the completed raft and also a structure to support the electrical interconnection between the sliver solar cells or the plank solar cells respectively. The cross beams can be fabricated from silicon or any other suitable material.

In an embodiment where the sliver cells or plank cells are mounted to a cross beam, thermal compatibility of the substrate is achieved by virtue of the small dimension of the adhered cross beam to the individual sliver or plank solar cells. That is, because of the small common area, the thermal expansion coefficient of the cross beam does not need to be as critically matched to the thermal coefficient of expansion of the sliver or plank cells as for some other forms of the invention. Ideally, for sliver cell applications, the cross-beam is formed from crystalline silicon to eliminate differential expansion problems. In the case of multi-crystalline plank cell applications, the cross-beam ideally may be formed from multi-crystalline silicon to eliminate differential expansion problems The solder raft cross-beams are preferably low cost, electrically insulating (either intrinsically or by way of coating with an insulating material), thin and capable of being selectively coated with solder-able metallised conductive tracks for electrical connections. Suitable substrates include silicon and borosilicate glass.

The sub-modules formed by using solder to provide electrical interconnections and to mechanically secure the sliver cells or the plank cells, respectively, to the cross-beams are referred to in this specification as “solder rafts” regardless of the type of solder used, the process used to deposit the solder and form the soldered electrical interconnections, or the type of solar cells used to construct the solder raft. The solder rafts can include a few to several hundred sliver solar cells or plank solar cells. The solder rafts can be formed in sizes similar to conventional solar cells, typically 10 cm×10 cm or even 15 cm×15 cm or longer. Further, there is no requirement that the sub-module assembly be square, or near-square. The number of sliver cells or plank cells in the sub-module can be selected to provide the desired sub-module voltage, for example. This allows the cells to be used in photovoltaic devices using similar techniques for encapsulation and electrical connection to those currently used for conventional solar cells. A significant difference is that each solder raft will usually have a much higher voltage and a correspondingly lower current than a typical conventional solar cell, depending upon whether the sliver or plank solar cells are connected in series or parallel.

In another embodiment, referred to in this specification as “solder boats”, the sliver solar cells, or plank solar cells respectively, are mounted on a continuous or semi-continuous substrate using solder to provide the electrical interconnections between adjacent solar cells as well as to establish the mechanical attachment of the solar cells to the solder boat substrate and also to provide the physical stability of the structure. The sub-modules formed by using solder to provide electrical interconnections and to mechanically secure the sliver cells or the plank cells, respectively, to the substrate are referred to in this specification as “solder boats” regardless of the type of solder used, the process used to deposit the solder and form the soldered electrical interconnections, or the type of solar cells used to construct the solder boat.

The solder boat substrate is thermally compatible inasmuch as it has a thermal expansion coefficient similar to that of the silicon in the solar cells in order to avoid stress during thermal cycling. The solder boat substrate is preferably low cost, electrically insulating (either intrinsically or by way of coating with an insulating material), thin and capable of being selectively coated with solder-able metallised conductive tracks for electrical connections. Suitable substrates include silicon and borosilicate glass. This form of sub-module is particularly suitable for applications under concentrated sunlight.

In this embodiment, the sliver solar cells or the plank solar cells may be closely positioned or spaced apart. Preferably the solder boat substrate is mounted on a heat sink so that the solar cells can be cooled via thermal transfer through the substrate. The structure may also incorporate an additional adhesive, if required, to provide extra mechanical stability of the heat sink or heat sink attachment. The adhesive may also assist with thermal conductivity to enhance the heat sinking properties of the device.

In yet another embodiment, the electrical and mechanical inter-connections between the sliver solar cells or the plank solar cells of the sub-module are formed solely by wires soldered to, and between, the electrodes of adjacent solar cells, removing the need for the cross-beams or substrate as well as the interconnecting metallised electrical tracks on a substrate. The sub-modules formed by using soldered wire interconnects to provide electrical interconnections and to mechanically secure the sliver cells or the plank cells, respectively, to form the sub-module assembly physical and electrical structures are referred to in this specification as “solder mesh rafts” regardless of the type of solder used, the process used to deposit the solder and form the soldered electrical interconnections, the type of wire used or the shape or form that the wire assumes, or the type of solar cells used to construct the solder mesh raft.

Both sliver solar cells, and plank solar cells, are particularly suitable for use in concentrated sunlight applications because the solder rafts, solder mesh rafts, and solder boats constructed according to this invention have a high voltage capability. The maximum power voltage of a sliver solar cell or a plank solar cell under concentrated sunlight is around 0.7 volts. In the case of concentrator sliver cells, the typical width of a cell is around 0.7 mm. Thus voltage builds at a rate of about 10 volts per linear cm in a direction along the sliver cell array with the advantage of a correspondingly small current. In the case of concentrator plank cells, the typical width of a cell may be up to one or two millimetres. Thus voltage builds at a rate of about 5 volts per linear cm in a direction along the plank cell array with the advantage of a correspondingly small current. In general, because plank solar cells may be wider than sliver solar cells, concentrator plank assemblies would normally be used in lower-concentration receiver applications compared with sliver concentrator receivers.

Consequently sliver solar cell solder rafts, solder mesh rafts, or solder boats and plank solar cell solder rafts, solder mesh rafts, or solder boats are particularly suitable for use in linear concentrator systems in place of conventional solar cells. In this regard each sliver solar cell or plank solar cell, respectively, can be series connected to its neighbour along the length (continuously or intermittently) of each edge using solder-based electrical interconnections. Electrical current consequently moves continuously along the length of the receiver, in a direction transverse to the length of the sliver solar cell, or plank solar cell respectively, rather than in a mixture of transverse and lengthwise directions, which essentially forms a helical spiral electrical current flow, as occurs when conventional solar cells are used. Additionally, the space occupied by the series inter-connections between the solar cells, be they sliver or plank cells, is very small so that little sunlight is lost by absorption in those connections.

Furthermore, and extremely significantly for concentrator applications, the solder-based electrical interconnections between sliver solar cells or plank solar cells utilised in concentrator applications as described above, results in the cell and receiver series resistance loss as being nearly independent of the width of the illuminated region.

The interconnection processes described herein have advantages that flow from the feature of sliver cells, along with most implementations of plank cells, that electrical connections are only required at the edge of each sliver solar cell. In the solder rafts, solder mesh rafts, or solder boats described herein, electrical connections are not required at, or along, the outer edges of a row of solder rafts, solder mesh rafts, or solder boats, corresponding to the narrow ends of the plank or sliver solar cells, because the functional electrical connections are provided by way of the conductive pathways on or in the substrate or cross-beams or wire mesh retention structure. This means that several parallel rows of solder rafts, solder mesh rafts, or solder boats can be used on a single receiver with only a narrow spacing between each row. The width of this narrow spacing need only accommodate thermal expansion, electrical isolation, and assembly constraints, and does not include the wide current buses running along both sides of the concentrator cells as required by conventional concentrator receivers.

Consequently, a sliver solar cell or plank solar cell concentrator receiver can be relatively wide, up to many tens of centimetres, and include several to many rows of concentrator cells, with a very high ratio of cell-to-receiver surface area coverage. This not only increases the effective efficiency of the concentrator receiver through improved area utilisation, but also reduces heat-loading imposed on the receiver through the attainment of a significantly reduced area of heat-absorbing, but not energy converting, components such as electrical interconnections and bus-bars. This has particular advantage in applications where multiple mirrors or wide mirrors reflect light onto a single fixed receiver. In this application each of the rows of solder rafts, solder mesh rafts, or solder boats will have a fairly uniform illumination in the longitudinal direction along the length of the receiver, although the illumination level may be different for each row. In these applications it is difficult to control series resistance and impossible to minimise wasted space between rows and cells, at least to the extent possible with sliver or plank concentrator solar cells, if conventional concentrator solar cells are used. This is not the case with the solar cell receiver modules constructed from solder rafts, solder mesh rafts, or solder boats.

A further advantage of the sub-modules described herein is that because the solder rafts, solder mesh rafts, or solder boats can be formed from sliver cells or plank cells the receiver voltage can be large so that the voltage up-conversion stage of an inverter (used to convert DC to AC current) associated with the photovoltaic system can be eliminated. A further advantage of the present invention is that each solder raft, solder mesh raft, or solder boat can be operated electrically in parallel to other solder rafts, solder mesh rafts, or solder boats. Alternatively, a group of solder rafts, solder mesh rafts, or solder boats can be series-connected and the groups can be run in parallel with other groups. This parallel connection ability can greatly reduce the effect on receiver output of non-uniformities in illumination, arising for example from shadows cast by concentrator system structural elements or optical losses at the ends of the linear concentration system.

It will be apparent from the foregoing description that the solder rafts, solder mesh rafts, or solder boats formed by the solder-based, adhesive-free interconnection processes described herein provide a significant advance over the prior art use of sliver solar cells and plank solar cells. In particular the placing of sliver cells or plank cells one by one into a photovoltaic module, or the performance penalty suffered by monolithic implementations of plank-like solar cells retained in the forming wafer during use, is avoided by the use of solder rafts, solder mesh rafts, or solder boats, with each sub-module assembly comprising 10s to 100s of individual sliver cells or individual plank solar cells.

Further, when compared with rafts, mesh rafts, and boats assembled using adhesives, and/or with the electrical interconnections established using conductive epoxies or similar conductive adhesive materials which require stencil or dispense processes for their application, the solder-based solder rafts, solder mesh rafts, and solder boats have the further advantage of excluding non-conventional materials. These non-conventional materials may have unknown or unconfirmed long-term stability and materials property reliability issues resulting from application within a solar module. For example, while the properties of conductive epoxy are quite well known in conventional applications, there is no data available on long-term exposure of this material to conditions typical for solar module installations. Some understanding can be obtained from accelerated life-time testing, but there is no short-term test that can reliably determine the synergistic effects of say, humidity, UV exposure, and thermal cycling over the long term for real field applications.

An even more significant advantage from the perspective of cost, throughput, reliability, and robustness of sliver cell and plank cell sub-module manufacturing processes, along with the associated manufacturing infrastructure that is required, is the opportunity that solder rafts, solder mesh rafts, and solder boats presents to eliminate any form of stencilling or dispensing of the solder material used in the process of establishing electrical interconnections and the formation and securing of the sub-module assembly structure. Because each such solder raft, solder mesh raft, or solder boat is small, it can be cheaply assembled in a mechanical jig that allows sufficient precision in the placement of the components. The integrity of the physical structure so formed, and the required electrical properties of the sub-module assembly, is provided by a single rapid and cheap solder process. The necessary number of solder rafts, solder mesh rafts, or solder boats can then be deployed to form the photovoltaic module with any desired shape, area, and power.

The solder rafts, solder mesh rafts, and solder boats described herein can be encapsulated and mounted on a flexible material such as Tefzel so as to form flexible photovoltaic modules by taking advantage of the flexibility of the thin sliver solar cells. Limited flexibility can also be provided for solder rafts, solder mesh rafts, and solder boats assembled using plank cells along the axis parallel to the cell. The sub-assemblies can be encapsulated and mounted on a flexible material such as Tefzel so as to form limited flexibility photovoltaic modules about one axis by taking advantage of the flexibility of the cross-beams or the wires used to construct plank cell-based modules. The solder interconnects between adjacent sliver cells and plank cells are sufficiently thin so as to provide the required flexing of the cross-beam. If a greater degree of flexing is desired, the solder interconnects can be made thinner for greater flexibility and wider to provide the conductor cross-section required so as not to exceed a specified maximum current density in the inter-connect materials.

Another method of taking advantage of the flexibility of solder rafts, solder mesh rafts, and solder boats fabricated using thin and flexible solar cells and crossbeams or substrates is to mount the solder raft, solder mesh raft, or solder boat conformally onto a rigid curved supporting structure. A particular advantage of solder-based sub-module assembly structures is that this mounting may be performed either prior to, during, or after the solder interconnections are established. It would be very difficult to achieve such a goal using some form of robotic “pick and place machine” for assembling the solar cells. Further, the solder raft, solder mesh raft, or solder boat may be assembled and processed on a curved former structure so that the completed sub-module assembly has the desired curvature profile. Alternatively, the solder raft, solder mesh raft, or solder boat can be mounted onto a flat supporting structure that is then curved to the desired shape. Sliver cell solder mesh rafts or solder rafts exhibit significant flexibility. The un-encapsulated assemblies can accommodate a radius of curvature of the order of 10 cm in a direction parallel or normal to the direction of the sliver lengths, but obviously not both at the same time. In the case of plank assemblies the radius of curvature is less, and is limited to a direction about an axis parallel to the plank cell length.

One example of a suitable supporting structure is curved glass for use in architectural applications. Another example is to mount the solder raft, solder mesh raft, or solder boat onto a curved extruded aluminium receiver for a linear concentrator. One advantage of so doing is that the individual solar cells in the solder raft, solder mesh raft, or solder boat will receive near-normal incident illumination along the entire length of the constituent sliver cells, even from sunlight reflected or refracted from the edge of the linear concentrator optical elements. In this particular application, sliver cells are more suitable than plank cells.

Another advantage of the solder rafts, solder mesh rafts, and solder boats described herein is provided by the ease of measurement of the efficiency of the sub-module assembly, and hence the aggregate efficiency of the constituent sliver cells or plank solar cells. The measurement of the efficiency of a large number of individual small solar cells is inconvenient, time-consuming, and expensive. The present invention allows the efficiency of the entire soldered sub-module assembly of solder rafts, solder mesh rafts, or solder boats to be measured in one operation, thus effectively allowing dozens to hundreds of small solar cells to be measured together. This approach reduces cost so that it is viable to sort the solder rafts, solder mesh rafts, or solder boats into categories of performance (including a fail category), and use appropriate solder rafts, solder mesh rafts, and solder boats for assembling photovoltaic modules with different performance characteristics.

A further significant advantage of soldered sub-module assemblies is that the solder electrical interconnections, in the absence of adhesives in the structure, allows the possibility of rework of the sub-module. A faulty or underperforming sliver cell, plank cell, group of sliver cells, or group of plank cells in the sub-module assembly may simply be replaced by melting the solder, and removing and replacing the faulty device or devices with a good cell or cells. The electrical interconnection of the reworked or repaired sub-module assembly is established by a localised solder reflow operation. Alternatively, those solder rafts, solder mesh rafts, and solder boats that have a performance below a selected level can be discarded or divided into sub-sections and remeasured. If the individual solar cells that cause the poor performance are primarily in one portion of the solder raft, solder mesh raft, or solder boat then some subsections may have good performance while another sub-section might need to be discarded because performance is not sufficiently good.

The solder rafts, solder mesh rafts, and solder boats also address difficulties that can occur during the fabrication of solar cells where it may be inconvenient or difficult to carry out some steps on small solar cells. For example it is difficult or impossible to metallise one of the faces of a sliver solar cell or group of cells in order to create a reflector on one surface while the cells or groups of cells are still embedded in the silicon wafer. Another example is the application of an anti-reflection coating, which in some circumstances may be more conveniently done after the metallisation of the electrodes has been completed. However, this carries the risk that the anti-reflection coating will cover the metallisation, making it difficult to establish electrical contact to each cell. If solder is selected as the material to establish electrical connections and to form the physical constraint material for the structure of the raft, mesh raft, or boat, then subsequent layers such as anti-reflection coatings and reflective coatings can be deposited by evaporation, chemical vapour deposition, spray deposition or other means on the sliver or plank sub-assembly structures during or after the time when the solder raft, solder mesh raft, or solder boat is assembled. All these additional processes can be completed without adversely affecting the reliability or function of the soldered electrical inter-connections.

Similarly, the solder-based processes described herein can provide a more convenient approach for electrical passivation of the surface of solar cells. Electrical passivation is sometimes carried out using a material such as silicon nitride deposited by a plasma-enhanced chemical vapour deposition (PECVD) or by depositing an amorphous silicon layer. These coatings obviate the need for high temperature processing in order to achieve good surface passivation. In some cases it is difficult, or impossible, to carry out this step during normal solar cell processing. For example, silicon nitride deposition by plasma enhanced chemical vapour deposition is not conformal. Consequently it is difficult to successfully coat the surfaces of sliver solar cells while they are still embedded in the silicon wafer. The process can, however, be successfully carried out during or after the assembly of the solder raft, solder mesh raft, or solder boat.

A photovoltaic device for a solar linear concentrator can include a plurality of solder-based rafts, mesh rafts, or boats constructed from sliver solar cells or plank solar cells, with sub-module assemblies positioned in a closely adjacent arrangement so that electrical current path and electrical current flow occurs substantially lengthwise along the receiver.

In accordance with a still further aspect of the present invention, there is provided a method for establishing sliver electrodes or plank electrodes with the thickness of metal necessary to reduce current density and resistance to below required threshold levels. In the case of sliver solar cells, the wafer containing the set of sliver solar cells is processed to establish a thin layer or film of metallisation which forms the base of the sliver electrode. This process can be performed in a Varian or similar device, with the metal film being nickel, copper, silver, or some other suitable metal, or some selection of layers of dissimilar metals such as copper over an aluminium base, or copper over nickel over aluminium, or tin over nickel for example. Evaporation is a reasonably expensive and wasteful process, with large areas of the vacuum chamber also being coated with the electrode material, although some of this excess material may be recycled. The volume, and hence cost, of the evaporated metal and the accompanying evaporation process can be limited by reducing the thickness of the evaporated film. The thin layer of evaporated metal on the sliver electrode can then be plated up to provide the required low resistance and low current density electrodes. There are several ways of achieving this, including the presently used process of electro- or electro-less plating. In the case of some forms of plank cells, such as plank cells with both electrodes on one cell face, conventional screen printing techniques can be used to form the electrodes.

A more convenient, reliable, and cheaper method is to plate up the thin prepared evaporated metal-base electrodes with solder. The metal surfaces on the slivers or planks in the wafer frame are coated with flux and the wafer is plunged into and removed from a molten solder bath. The excess solder adhering to, and forming an alloy with, the electrode metal base is removed with a hot-air knife. The solder will only adhere to, with the formation of a metal-solder alloy, and coat, the metallised areas of the relevant electrodes. The excess solder, including any solder that forms bridges between adjacent cell electrodes, is removed by the hot-air knife as the wafer is removed from the solder bath.

With this method of plating up cell electrodes, it is important to limit the time that the solder, which is in contact with the evaporated metal film, is above liquidus in order to reduce the thickness of the metal film on the electrode that is dissolved in the liquid solder which forms the plated-up electrodes during the plating process. The thickness of the evaporated metal material required to form the electrode base is a function of the type of solder metal alloy, the type of metal used on the surface of the evaporated electrode base, the solder temperature, the flux type, the type of gas surrounding the wafer above the solder bath, and the time the solder in contact with the evaporated metal film is above liquidus.

For example, the typical thickness of metal required for the electrode base is around 1 micron for silver, 3 to 4 hundred nanometres for copper, and 1 to 2 hundred nanometres for nickel. These figures can alter substantially if a multi-layer base is formed with different metals, for example by using a nickel barrier layer under tin or copper, or for tin or copper over an aluminium base layer. In some circumstances, depending on the choice of finished electrode surface metal, the application of a gold flash a few tens of nanometres thick may be advantageous.

The solder bath used for plating-up cell electrodes is typically around 265° C. for tin/lead solder and may be up to 295° C. or higher for lead-free solders, while the hot air knife temperature is approximately the melting point of the solder which is being used. The air-knife temperature, and the air flow rate, can be adjusted to assist with controlling the thickness of the solder-plated electrode. If a thicker electrode is required, the knife temperature and/or the air flow rate, is reduced. Conversely, if a thinner electrode is required, the air-knife temperature, angle of attack, and flow rate is increased. Using an inert gas such as nitrogen can assist with more precise control of the plated-up layer properties. The choice of flux is determined by the choice of metal, the condition of the metal surface, and the solder type. This process is also very suitable for lead-free solder applications, although it will be evident to those skilled in the art that lead-free solder application of electrode material will require changes to most process parameters including temperature, flux type, and time. In some applications it may be advantageous to use nitrogen in the hot-air knife.

An entirely analogous procedure can be constructed by adapting the above process to the particular requirements of plank solar cells.

The detailed procedures for the initial handling and separation of the sliver cells from the wafer and methods for assembling the separated silver cells into rafts, mesh rafts, and boats are provided in International Patent Application No. PCT/AU2005/001193. These methods of establishing an array of sliver cells in the required relative positions will not be repeated here. However, in accordance with a further aspect of the present invention, there is here provided several methods of retaining sliver solar cells which have been already removed from the wafer frame and are presented in an un-bonded array format in the physical form, or planar array structure or arrangement, of rafts, mesh rafts, or boats. The sliver array so presented has the required number of sliver cells in the correct electrical orientation and the correct physical planar spacing arrangement. The planar arrangement embodies the desired relative location and orientation of sliver solar cells in the completed solder raft, solder mesh raft, or solder boat array.

In addition to the vacuum separation and stamp arrangement detailed earlier for establishing an array of separated plank solar cells, which is ideally suited for full-cover arrays such as plank boats, or spaced arrays where the spacing between cells is some integral multiple of the cell width or pitch in the forming wafer. In addition to this restricted ratio spacing, a process has been devised whereby the plank solar cells can be formed in array spacings with any desired pitch. In this process, the plank solar cells are dispensed from a slotted multi-stack cassette in a process identical to that used to dispense multiple sliver cells in the form of planar arrays from which rafts, mesh rafts, and boats are constructed. The slotted walls of the multi-stack cassette form the array spacing as with the sliver cell raft assembly technique described in International Patent Application No. PCT/AU2005/001193. The only functional variation required for plank cell assembly is that the retention mechanism at the base of the slots in the multi-stack cassette needs to be flexible to compensate for the reduced flexibility of plank cells when compared with sliver cells.

Alternatively, but not necessarily preferentially, a de-stacking routine can be used to singulate a plank from each slot of the multi-stack cassette, producing a planar array of planks equal to the number of slots in the cassette, in a single routine sequence, from the base of the cassette. In this form of the invention, de-stacking involves engaging the bottom plank with a vacuum head or sticky surface, moving the plank longitudinally into a slot a distance slightly greater than the retaining lip at the base of the cassette, which then frees one end of the plank. This end is moved downwards to clear the retaining lip, then the plank is moved longitudinally back towards the freed end to release the plank end still in the horizontal slot. The horizontal slot dimensions are such that the plank profile at the end of the plank has clearance within the slot with the maximum dimension tolerance plank, but there is not sufficient room within the slot for two minimum dimension planks. This ensures that one, and only one, plank can be removed via the de-stacking mechanism.

In all other respects, the formation and presentation methods of planar cell assemblies, the receiving and handling of the planar or near-planar assemblies, and the subsequent electrical connection methods and process for sliver cells and plank cells are essentially interchangeable, requiring only minor adaptations of jigs and vacuum heads for example, in order to accommodate the physical differences in the size of the planks and slivers.

The ability to fabricate stand-alone solder rafts, solder mesh rafts, and solder boats simplifies the handling and assembly of sliver solar cells and the construction of PV modules. Adaptations of these methods, mostly involving only dimensional changes to the jigs, clamps, or vacuum heads for example, provide the same level of simplification when handling and assembling plank solar cells. The assembly of sliver cell rafts, mesh rafts, or boats planar arrays, and plank cell rafts, mesh rafts, or boats planar array arrangements can be accomplished with small, cheap devices that do not require large-scale accuracy and automation such as devices previously thought to be necessary for sliver solar cell module assembly, and not widely contemplated for plank cell assembly on a large scale.

Furthermore, the tasks required for the assembly of solar modules, such as stringing and encapsulating the rafts, mesh rafts, or boats, —regardless of whether the sub-assemblies are constructed from plank solar cells or sliver solar cells—can be performed with very slightly modified conventional PV assembly equipment. An added very attractive feature is that sliver solar cell sub-module assemblies and plank solar cell sub-module assemblies such as solder rafts, solder mesh rafts, and solder boats can be made using conventional materials, thus providing much greater confidence in the long-term reliability of the module.

### BRIEF DESCRIPTION OF THE DRAWINGS

Preferred embodiments of the invention are hereinafter described, by way of example only, with reference to the accompanying drawings, wherein:

FIG. 1 is a schematic view of a solar cell “solder raft” sub-module according to an embodiment of the present invention;

FIG. 2 is a schematic view of part of the solder raft shown in FIG. 1 showing one form of soldered electrical interconnection;

FIG. 3 is a view similar to FIG. 2 showing one form of soldered electrical interconnection for a “solder boat”;

FIG. 4 is a view similar to FIGS. 2 and 3 showing yet another form of a soldered electrical interconnection in a solder raft or solder boat, in which solder-based conductive paths on the crossbeam or substrate connect the two edges of a sliver cell together;

FIG. 5 is an end view of a solar cell solder raft or solder boat according to the present invention showing the mounting, securing, and electrical connections of sliver solar cells on a substrate;

FIG. 6 shows another embodiment of a solar cell soldered sub-module in one form of a solder boat, according to the present invention for use in a solar concentrator system;

FIG. 7 is a plan view of a mechanical clamp and assembly jig used to physically retain the planar arrangement of sliver cells and cross-beams for a solder raft during the soldering process;

FIG. 8 is an image of a solder raft showing the soldered electrical connections on the cross beam. The solder and the cross beams holds the sliver cells in place to form the solder raft sub-assembly structure;

FIG. 9 shows a detail image of a soldered interconnect pad. The outline and profile of the solder pad, including the solder distribution, is an important feature which is described further in the detailed description of the drawings;

FIG. 10 shows a detail of a sliver edge, the sliver electrode, and the solder joint of a solder raft;

FIG. 11 shows a detail cross-section of a solder joint, including the solder, sliver electrode, sliver, and cross-beam of a soldered raft joint;

FIG. 12 shows a cross-section of an entire solder inter-connection as well as the raft cross beam. This cross-section illustrates the distribution of the solder in the solder inter-connection and highlights the importance of the metallised pad topology in controlling the solder distribution in the joint;

FIG. 13 is an image of a functional mini-module constructed using a soldered raft and soldered external connections. This mini-module demonstrates the technology built on silicon slivers, soldered electrical interconnections, and solder-based physical assembly constraint. This working mini-module contains only conventional solar module materials;

FIG. 14 shows soldered sliver interconnections on a solder boat assembly;

FIG. 15 shows a detail of the soldered sliver interconnections on a solder boat assembly;

FIG. 16 shows a multi-stack cassette with vacuum sliver array extraction head and cross-beam mechanical support, positioning, and receiving table for the formation of sliver solar cell raft assemblies;

FIG. 17 shows a detail view of a multi-stack cassette with detail of the vacuum sliver array extraction head, cross-beam mechanical support, positioning, and receiving table, with a formed sliver solar cell raft assembly in place; and

FIG. 18 is a schematic perspective view of a set of sliver solar cells retained within a wafer frame, a quarter of which has been removed in order to view half of the slivers.

### DETAILED DESCRIPTION OF THE PREFERRED EMBODIMENTS

The processes described below involves the use of sliver solar cells to form two products: a sliver solar cell solder raft suitable for incorporating in a static concentrator solar power module, and a sliver solar cell solder boat suitable for application in concentrator receivers. The processes described in the formation of both of these products apply equally well to the formation of plank solar cell solder rafts and plank solar cell solder boats, with simple dimensional changes required to the equipment used. The same provision of inter-changeability between plank solar cell and sliver solar cell separation, handling, and assembly methods, processes, and products also applies to rafts, mesh rafts, and boats.

International Patent Application No. PCT/AU2005/001193 describes processes for forming assemblies or sub-modules of elongate substrates. Such sub-modules facilitate handling of elongate substrates and their assembly into larger modules. In particular, such sub-modules can be provided in a size substantially equal to that of a standard wafer-based solar cell to facilitate the above, and also to allow the use of standard processes and handling equipment in some instances. Three forms of assembly or sub-module have been found to be particularly advantageous. In one form, referred to for convenience as a “raft” sub-module, an array of parallel elongate solar cells are supported on crossbeams perpendicular to the elongate solar cells. In a second form, referred to as a “mesh raft” sub-module, an array of parallel elongate solar are interconnected by connectors lying in the plane of the array. In a third form, referred to as a “boat” sub-module, a plurality of parallel elongate solar cells are supported on a planar substrate that extends beneath the array of elongate cells.

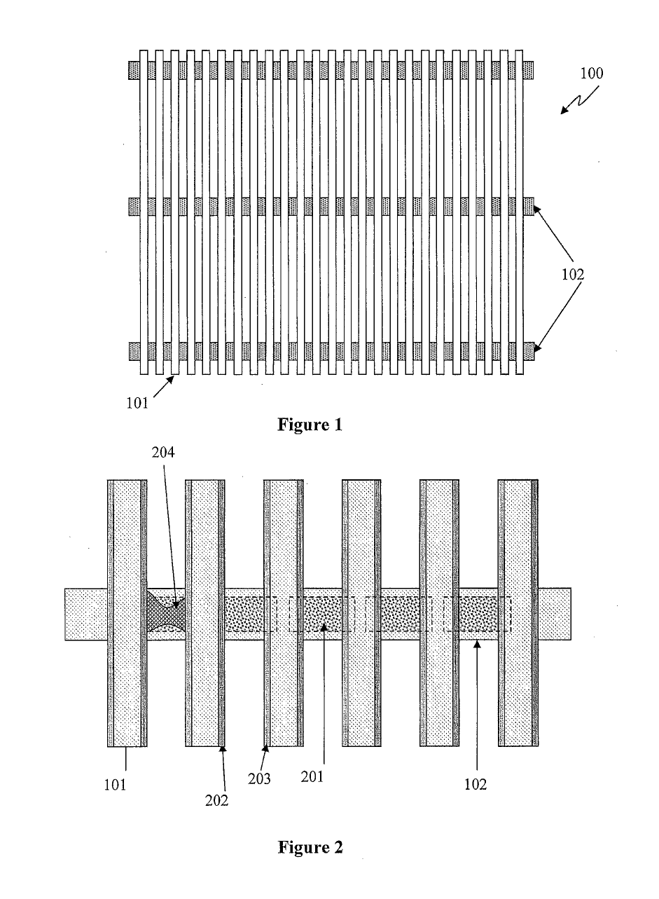

Referring to FIG. 1, elongate solar cells 101, either plank solar cells or sliver solar cells, and crossbeams 102 are assembled to form a sub-module assembly herein referred to as a “solder raft” 100. The spacing between the solar cells 101 can range from zero to several times the width of each cell. The crossbeams 102 are preferably thin, and can be made of any material that is electrically insulating, or is coated with an insulating material, and that can be readily coated with solder-able metallised conductive tracks or pads, as described below. For example, thin silicon slivers 30 to 100 micron thick, 1 to 3 mm wide, and 2 to 20 cm long are suitable crossbeams.

The metal used to form the tracks or pads on the cross-beams can be silver, nickel, tin, copper or other suitable solder-able metal, or composite layers of such metals or other combinations of metals such that the metal on the surface is solder-able. For example, a chromium or nickel barrier layer may be applied to the cross-beams or base-layer metal, with an easily solder-able metal such as copper, tin, or silver deposited on top. The metal or metal layers can be applied directly to the cross-beam by vacuum evaporation, or can be made from small, suitably shaped pieces of foil or shim bonded in the required location to the cross-beam surface by an adhesive that withstands soldering temperatures. The cells 101 are mechanically attached to the crossbeams 102 by the solder which also forms the electrical inter-connections between adjacent sliver or plank electrodes, or between electrodes or parts of electrodes in the case of some forms of solder boats.

Alternatively, the crossbeams 102, made of thin material, which is not electrically conductive, or an electrically conductive material coated with a suitable insulating material barrier, can be selectively coated with a solder-able compound material such as a metal-loaded epoxy, metal-loaded ink, metal loaded paste, metal loaded polymer, or metal loaded paint to form the metallised conductive tracks or pads.

Suitable materials in the polymer range include Dow Corning PI-1000 Solder-able Polymer Thick Film which produces an “active” screen-printable and dispensable material with outstanding electrical and thermal conductivity. The pads or electrical inter-connect tracks can be directly soldered with no further surface preparation or metallisation. Other materials in the paint range include E-KOTE3030, which is a solder-able air-drying modified acrylic silver paint. Again, the paint, which can be pad-printed, screen-printed, or mask-sprayed, can be directly soldered without further surface preparation or metallisation. Materials in the conductive epoxy range include TRA-DUCT 2902, which is an electrically conductive, silver-filled epoxy adhesive that provides a conductive bulk with a solder-able surface. There is a large range of suitable materials known to those skilled in the art, that can be substituted for the above examples, while still delivering satisfactory results. Alternatively, a conventional solder-able material, widely used in the PV industry for forming solder-able surface contacts on conventional cells, such as Ferro-Corp 3347 ND silver conducting paste, can be screen printed and fired to form a solder-able surface. Again, there are many alternatives to this product which are readily available and known to those skilled in the art.

The advantage with these types of materials for pad and track formation is that pad location and size accuracy requirements are significantly reduced since the pad can protrude under the sliver for almost half the sliver width without causing bridging of the electrodes during the solder process. A further advantage is that the use of expensive material is minimised since the only purpose of the track or pad is to provide a solder-able surface. The pad or track itself is not required to carry any appreciable current since the cross-section of the solder interconnects carry the bulk of the current.

For example, thin silicon slivers 30 to 100 micron thick, 1 to 3 mm wide, and 2 to 20 cm long are suitable for the crossbeams. The material used to form the tracks or pads on the cross-beams, such as metal loaded polymer, paint, epoxy, or paste is applied in a process such as mask spraying, screen printing, pad printing, or stencilling for example, suitable for the material chosen such that the processed surface is solder-able. For example, a silver loaded paint such as EKOTE3030 is pad-printed to the cross bar substrate and air dried in preparation for the solder process. The cells 101 are mechanically attached to the crossbeams 102 by the solder which also forms the electrical inter-connections.

Referring to FIG. 2, serial or parallel electrical connections between the solar cells 101 can be effected by forming solder bridges between adjacent sliver or plank electrodes. For example, series connections can be formed by connecting the n-contact 202 to the p-contact 203 of the adjacent cell with a solder bridge 204. The solder bridge 204 can be made by using intermittent patterns of metal or solder-able material 201 applied to the crossbeams to form a solder-able surface, which is subsequently used to retain molten solder in the appropriate location to form the electrical connection through the bulk solder alloyed to the sliver or plank electrodes. The solder, also alloyed to the solder-able surface, performs the dual function of providing the physical restraint to secure the soldered sub-module assembly, as well as providing the required electrical inter-connections. Electronic devices such as bypass diodes or logic devices can be included in the circuit with the existing or additional solder connections providing the same physical and electrical functions.

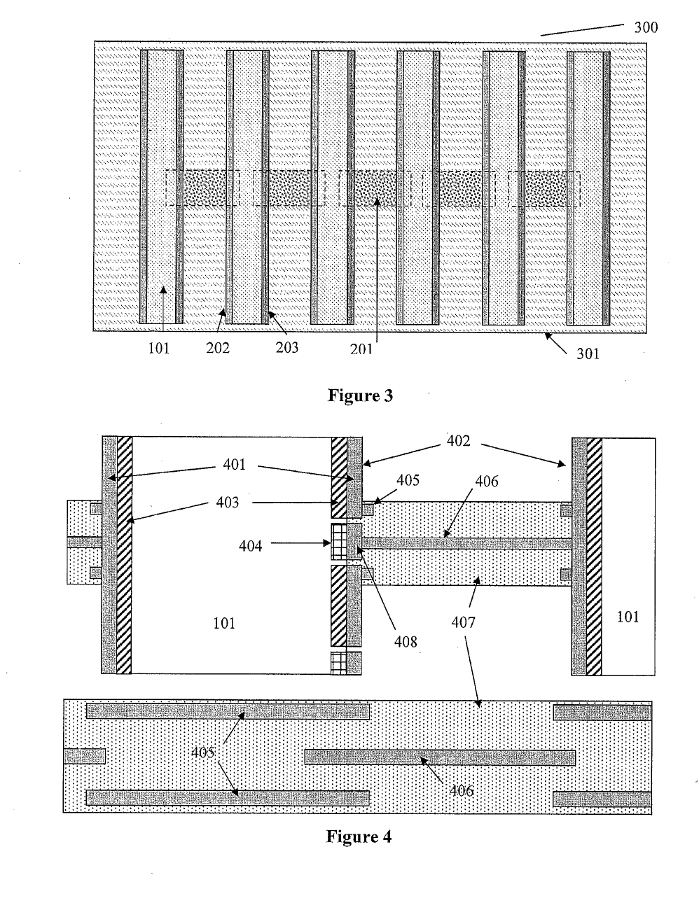

In an alternative embodiment, as shown in FIG. 3, the solar cells 101 can be assembled on a continuous or semicontinuous substrate 301 to form a sub-module 300 hereinafter referred to as a “solder boat”. The spacing between the solar cells can range from zero to several times the width of each cell. The substrate 301 is preferably a non-conductive material (or is coated with an insulating material), can be readily coated with a metallised track 201, or a solderable paint, epoxy, polymer, or paste 201, and has a similar thermal expansion coefficient to silicon. Silicon and borosilicate glass are suitable substrates. Alternatively, a pliant material can be used that will not place excessive thermal expansion mismatch stress on the solder boat during thermal cycling.

In either of the above embodiments, a plurality of small solar cells such as sliver solar cells or plank solar cells can be used to form photovoltaic solder rafts, solder mesh rafts, or solder boats, where the solder rafts, solder mesh rafts, or solder boats have a similar size to, and can directly substitute for, conventional solar cells. The solar cells with the sub-module assembly can be connected in either series or parallel or a mixture of series and parallel to deliver a desired solder raft, solder mesh raft, or solder boat voltage. If the solder raft, solder mesh raft, or solder boat voltage is sufficiently large that the solder rafts, solder mesh rafts, or solder boats can be connected in parallel, then the effect on module output of a module constructed from these solder raft, solder mesh raft, or solder boat devices, one or more of which has a low current (for example, caused by partial shading or sub-module mismatch for example) will be less than in a conventional photovoltaic module.

An additional use for conductive tracks on the crossbeam or substrate is to electrically connect one sliver or plank edge electrode to the other edge electrode, of the same or opposite polarity as required, of the same sliver cell or plank cell respectively. For example, the n-contacts on one edge of the sliver cell could be connected to n-contacts on the other edge of the same cell. The p-contacts on one edge of the sliver cell could be connected to p-contacts on the other edge of the same cell. The n and p contacts on the sliver would remain electrically isolated from each other to avoid short-circuiting the cell. In this configuration, the metallised track or solder-able material needs to have sufficient intrinsic conductivity, with the solder between the electrode and each end of the track forming an electrical connection to the track as well as the physical function of attaching the sliver to the substrate. This also applies to plank solar cells in this arrangement.

Alternatively, a two-step soldering process can be used where the metallised or solder-able tracks or pads are tinned with solder prior to assembling the raft or boat. This ensures adequate conductivity through the presence of solder, which may not be able to coat the entire pad or track region lying under the sliver or plank solar cell in a single-step soldering process with the solar cell already in place over the pad or track.

One reason for connecting the two edges of the same narrow solar cell together electrically is to reduce electrical resistance losses. This is particularly important for wide sliver cells or sliver cells configured for use under concentrated sunlight, and even more important for plank solar cells under similar circumstances. The resistance loss is proportional to the square of the solar cell width between the electrodes. If n and or p contacts are present on both solar cell edges, then the effective width of the cell (for electrical resistance purposes) is halved and the resistance loss is quartered. Thus, the solar cell can be twice as wide and yet have the same resistance loss as for a cell with only n-contacts on one edge and p-contacts on the other edge.

FIG. 4 shows one arrangement wherein the crossbeams 407 of a solder raft are used to electrically connect together the two edges of the same polarity 401 of an elongate solar cell. A similar function could be achieved using a solder boat substrate rather than a crossbeam. In this case only the n-contacts 401 of the n-diffusion 403 on each edge of the sliver cell 101 are electrically connected using the tracks 405 on the cross beam 407. This is suitable for a cell in which electrical resistance in the n-type diffused emitter (which covers the broad face of each sliver cell and bifacial plank solar cells) dominates the total electrical resistance of the solar cell. If the electrical resistance in the substrate is also an important consideration, then both n and p contacts can be present on each edge of the solar cell and can be independently electrically connected in this manner.

Series connections between adjacent cells 101 are established from the p-contact 408 on the p-diffusion 404 of one cell to the n-contact 402 on the adjacent cell via the track metallisation 406.

Some solar cells such as sliver solar cells and many forms of plank solar cells have metallisation on the solar cell edge. During solder raft, solder mesh raft, or solder boat assembly (and for other purposes) it is sometimes convenient that the solar cell metallisation wrap around onto the face of the solar cell immediately adjacent to the edge. Details of how this can be accomplished for sliver cells, for example, are provided in International Patent Application No. PCT/AU2005/001193.

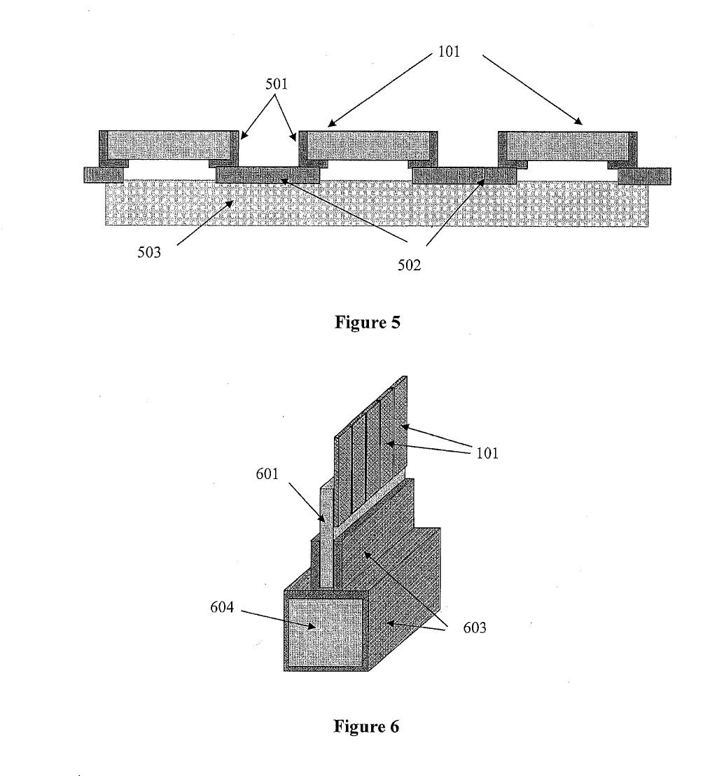

Referring to FIG. 5, solar cells 101 that have partial metallisation on the cell face 501 allow for the solar cell to be soldered or electrically connected directly to conductive tracks 502 on the crossbeams or substrate 503. The conductive tracks, which present a solder-able surface, can be applied to the crossbeams or substrate beforehand by screen printing, evaporation, pad printing, stencilling, dispensing, spray mask painting or similar techniques. The connection 502 between the solar cells and the crossbeams or substrate provides electrical connection, thermal connection and, via solder to the angled evaporation electrode, adhesion of the sliver cell or plank cell to the substrate or cross-beam.

If the solar cells are spaced apart from one another when mounted on the crossbeams or substrate, then some of the sunlight will strike the crossbeams or substrate. The cross-beams or substrate can be textured or roughened, a process easily undertaken if the cross-beams or substrate is silicon, and can be coated with a reflective material in such a way that the electrical connections are not shorted, so that most of this light is reflected and scattered in such a way that a large fraction is trapped within the photovoltaic module and has a high probability of intersecting a solar cell. In particular, if the cross-beams are mounted away from the sunward surface of the sliver cells or plank cells, then the effective shading of the cross-beams is reduced.

It may be advantageous to space the solar cells apart from one another. The required conductivity of the extended tracks is easily accommodated for by increasing the cross-sectional area of the solder inter-connects as determined by the resistivity of the material. For example, this will reduce the number of solar cells required per square metre. Provided that a reflector is placed behind the solar cells, then much of the light that passes between the gaps will be reflected and will intersect a solar cell. Light striking the surface of the solder will be reflected, with sufficiently high-angle reflections being totally internally reflected by the module surface, and the reflected light having a high probability of striking a cell on subsequent reflections. In the case of a sun-tracking concentrator, the range of angles of incident light is considerably smaller than in the case of a non-tracking photovoltaic system. This allows a suitable reflector to be designed with much higher performance than in the case of a non-tracking system (as allowed for by the fundamental laws of optics).

It may be advantageous to space the solar cells apart from one another in order to specifically ensure a more uniform distribution of light onto each surface of a bifacial solar cell. For example, in concentrator systems, electrical series resistance losses in the emitter of a bifacial sliver solar cell or plank solar cell are a large loss mechanism. If half of the light can be steered to the surface away from the sun then the series resistance losses will be halved.

In photovoltaic modules that require that the solar cells be heat-sunk, the solar cells can be thermally connected, as well as electrically connected to the crossbeams or substrate using the solder material used to create electrical connections between the solar cells. In turn, the crossbeams or substrate can be attached to a suitable heat sink. This process does not require the separate application of thin electrically insulating layers to obtain good thermal connection between the solar cells and the heat sink without electrical conduction. Electrically isolated solder dots or pads, formed in the same way as the electrically interconnecting pads or tracks, and soldered at the same time as the electrical connection solder process, can be used to directly provide thermal contact between the sliver cell with the substrate, or between the plank cell and the substrate, without compromising the electrical circuit integrity.

Silicon is a highly thermally conductive material. Even when illuminated by concentrated sunlight, it is unnecessary that the whole of one surface of the solar cell be directly connected to a heat sink. Heat may conduct laterally within the silicon solar cell to a region where heat sinking is accomplished. In the case of solder rafts and solder boats, heat sinking can be accomplished by the soldered electrical interconnections, interspersed with isolated electrode-to-substrate soldered thermal connections as required. In the case where solar cells are electrically connected edge-to-edge, not every solar cell may need to be connected to a heat sink, and the connections to the heat sink may not need to be made along the entire length of the sliver cell or plank cell in the solder boat form. Heat may flow from one solar cell through the electrical connection to another solar cell that is attached to the heat sink.

Alternatively, heat may conduct from illuminated regions of a solar cell to non-illuminated regions of the solar cell where heat sinking may take place. Referring to FIG. 6, a row of solar cells 101 is mechanically bonded to a substrate 601 with a matched thermal expansion coefficient such as silicon. Advantage can be taken of the bifacial nature of some solar cells such as sliver solar cells and bifacial forms of plank solar cells to allow illumination on both surfaces of the solar cells. Electrical conduction occurs from solar cell to neighbouring solar cell. Thermal conduction occurs along the length of the cell at right angles to electrical conduction which occurs across the solar cell. The heat passes into the substrate 601 and thence into a heat sink 603 (which can be solid or liquid 604). The optimum length of the solar cell is partially determined by the temperature of the solar cell at the end of the cell away from the heat sink, the temperature of the heat sink itself, and the length of the cell.

A set of sliver cells is formed in a wafer according to the technique described in WO 02/45143. Details of the methods of extracting sliver cells from the wafer, subsequent handling and buffer storage, assembly procedures, and the mechanisms used to form a planar array of sliver cells with the correct orientation and with the correct spacing between adjacent slivers are provided in International Patent Application No. PCT/AU2005/001193.

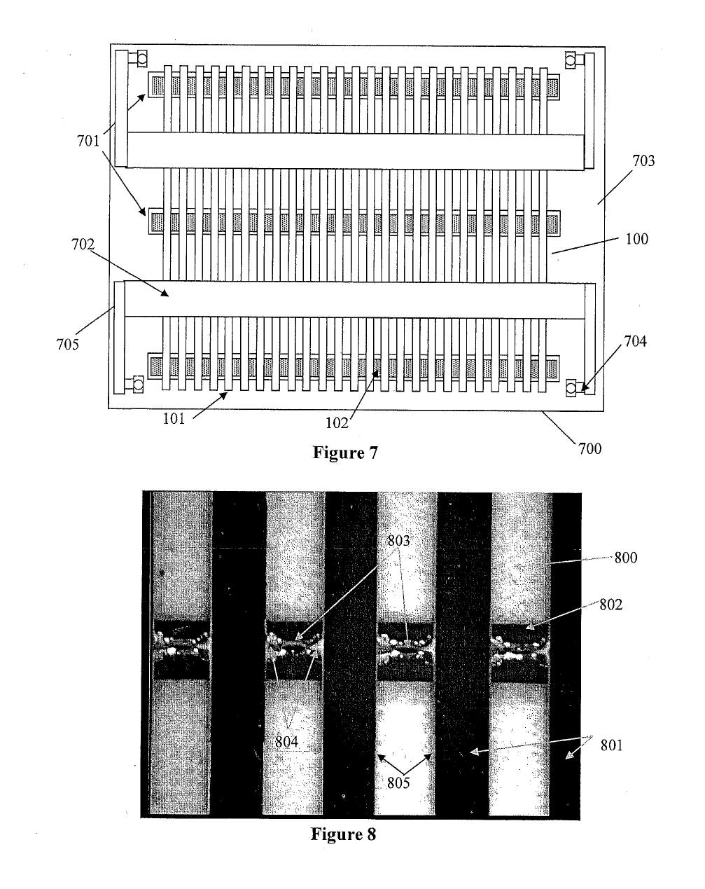

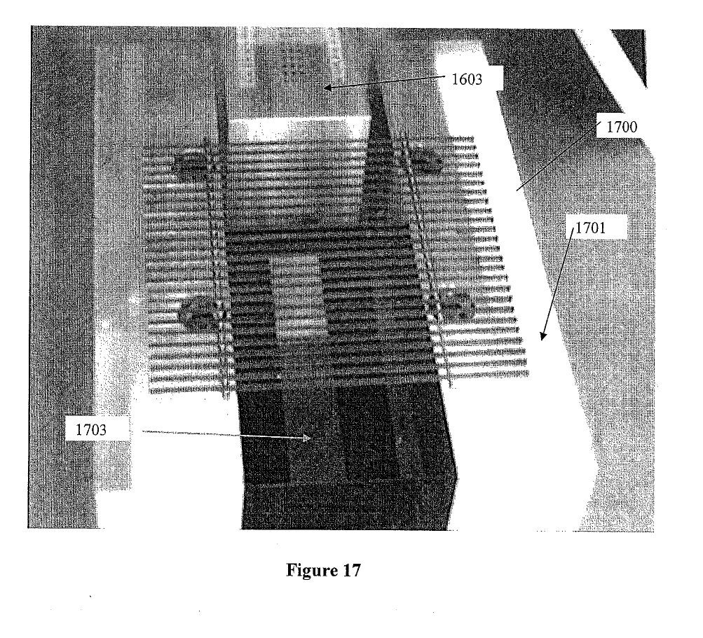

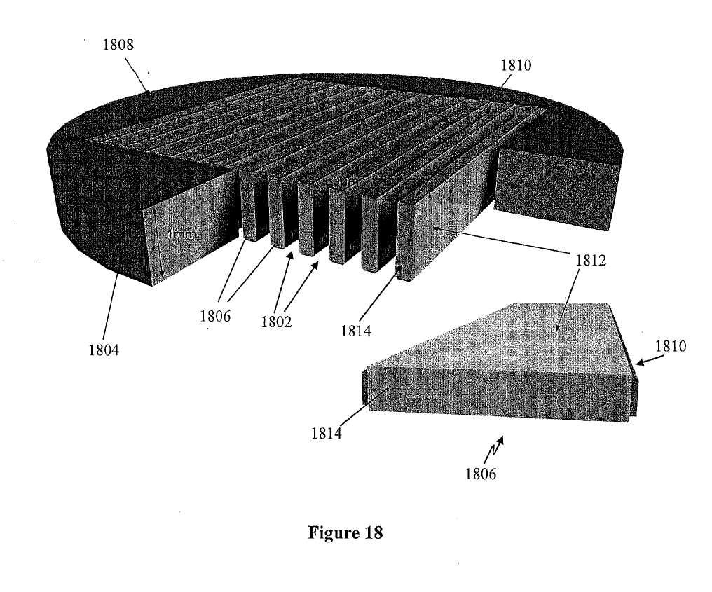

One method for forming an array of slivers cells, equally applicable to plank solar cells, provided in the above-mentioned document involves the use of a vacuum engagement tool to extract and transfer an array of sliver cells from an array of wafers or an array of previously extracted sliver cells from an array of buffer storage cassettes and move the array to the next stage of sub-module assembly, such as placing the array on cross-beams to form the physical arrangement of a solder raft 100, such as that as shown in FIG. 1. Such a tool is shown in FIG. 16. The raft cross-beams 102 have been previously prepared with metal pads 201, metallised pads or tracks 201, or solder-able pads or tracks 201 prepared from solder-able polymer, epoxy, paste or ink using dispensing, stencil printing, vacuum evaporation, screen printing, mask spraying, stamping or other well-known method of transferring the desired quantity of metal, metallised surface, or solder-able material to the required location. The loosely-formed sub-module array 100 such as that shown in FIG. 1 and FIG. 17 is then mechanically clamped as shown in FIG. 7 to preserve the relative locations and orientations of the slivers in the sliver array and the cross-beam during the subsequent soldering process.

Referring to FIG. 7, the raft assembly 100 is transferred to the solder raft clamp 700. The solder raft clamp 700 includes a planar clamp base 703 in which a series of parallel mutually spaced elongate recesses or grooves 701 have been formed. The clamp 700 also includes two securing beams 702 supported by one end of support arms 705. The other end of each support arm 705 is attached to a hinge or pivot 704 which allows the securing beams 702 to be swung into place, as described below. Advantageously, the solar cell array 100 is transferred to the solder raft clamp 700 whereon the cross-beams 102 have been previously placed in locating grooves 701 which leave the top surface of the cross-beams slightly raised above the clamp surface. The cell array 100 is placed on top of, and substantially perpendicular to, the crossbeams 102, the securing beams 702 are swung into place by way of the support arms 705 and the hinges 704 so that the securing beams 702 engage mutually spaced portions of each elongate solar cell of the array 100 to secure the array 100 and the crossbeams 102 and thereby maintain their relative orientations and locations. The support arms 705 are preferably recessed or bent, with the arms 705 fitting into slots or grooves in the clamp base 703 so that no parts of the arms 705 protrude above the plane of the clamped solar cells 100 along the line taken by a selective wave solder fountain during the soldering process.

The mechanical clamp 700 shown in FIG. 7 is just one of several possible apparatuses for physically securing the unfinished solder raft sliver array 100 and cross-beams 102 in appropriate relative positions in preparation for and during the soldering process. Other alternatives include a vacuum clamp assembly where the solar cell array 100 is held in position on a planar or near planar surface with recesses for receiving the cross-beams as described above, but including vacuum through holes in the surface and in the recesses, where the vacuum retention holes coincide with the locations of the sliver cells or plank cells and the crossbeams. Alternatively, the recesses can be omitted; since the cross-beams are only 30 to 50 microns thick, the elongate cells can be held by the vacuum over most of the planar surface, bending slightly where they cross over the cross-beams. One advantage of the vacuum retaining assembly plate is that the entire solar cell raft surface is unobstructed over the surface of the raft in preparation for the soldering process.

In yet another alternative, the loose (i.e., unsoldered) solar cell assembly and cross-beams are retained on a sticky surface in preparation for and during the solder process. The sticky surface is preferably re-useable, and may provide a permanent or semi-permanent coating such as a silicone, polymer, or mastic material with a durable and clean-able surface. Alternatively, the sticky surface may be single-use. This can be provided by a UV-degrade-able adhesive or solvent-removable adhesive applied to select portions of the assembly clamp to retain the solar cell assembly and cross-beams in preparation for and during the solder process. Alternatively, the loose solar cell assembly and cross-beams can be retained by double-sided sticky tape or similar material in preparation for and during the solder process.

Alternatively, the loose solar cell assembly and cross-beams can be retained on the assembly clamp by the use of Kapton adhesive tape or similar heat-resistant adhesive material. Kapton tape is heat-resistant, and protects against tape shrinkage and deformation under solder temperatures, such shrinkage and deformation possibly altering the relative location of adjacent solar cells, the entire solar cell array, and/or the cross-beams. Further, the adhesive material on the Kapton tape is not damaged or degraded or has its performance adversely affected by exposure to soldering temperatures during the raft soldering process. When Kapton tape is used, the loose solar cell assembly and cross-beams are taped to a printed circuit board former or blank. The printed circuit board material is designed to withstand solder temperatures, may be re-used many times, and also has a low specific heat, compared with metal forming clamps or bases, that allows the solar cell and cross-bar material to rapidly rise to soldering temperature and then rapidly fall below soldering temperature in order to minimise the length of time that the solder and solar cell electrode material temperature is above solder liquidus.

A wave soldering process is used to avoid the dispensing or stencilling or printing operations that would otherwise be used to deposit solder and flux paste onto the metallised or solder-able pads or interconnects for the subsequent reflow to form electrical interconnections and the physical stability of the sub-module solder raft, solder mesh raft, or solder boat. Selective wave soldering has been found to give excellent results for establishing electrical interconnections and providing physical stability in the absence of adhesives on solder rafts, solder mesh rafts, and solder boats.

The selective wave solder process is performed using an EBSO SPA 250, or an EBSO SPA 400 selective wave soldering system, or similar selective wave solder machine. These machines feature a programmable track traverse, have a titanium solder bath unit which is suitable for lead-free as well as conventional soldering, and provide an inert nitrogen atmosphere around the solder fountain. A range of solder nozzles is available so that the width, height, flow rate and collapse profile of the molten solder fountain can be selected to ensure a good solder joint. It should be noted that it is not necessary to use the aforementioned selective wave solder machine. It will be apparent to those skilled in the art that there are many ways of implementing a selective wave solder process, ranging from a basic manually-driven process to a fully-automated in-line process.

The process of soldering sliver solar cell rafts, mesh rafts, and boats, and plank solar cell rafts, mesh rafts, and boats falls far outside mainstream electronics and circuit-board soldering technology, and presents several unique and significant challenges. In particular, the very thin evaporated or plated electrodes that are sufficiently thick to carry the cell current along the electrode between the cell-to-cell interconnections, may dissolve in solder, sometimes in less than one second, at temperatures required to ensure good wetting of the electrodes and the interconnecting pads or tracks. This means that the interval of time that the solder in the joint is above liquidus needs to be kept as short as possible, preferably well below one second, and more preferably in the range of 0.3 to 0.5 second. This precludes conventional reflow processes unless the sliver cell electrodes are plated up thick enough to eliminate the problem associated with dissolving of the electrode during the time that the joint is above liquidus. This raises electrode material and deposition process costs to unacceptably high levels.

In the case of sliver solar cells, because the sliver cells and cross-beams are very thin, of the order of 50 μm to 100 μm, the thermal mass of the sliver cell raft, mesh raft, or boat is very small. Further, silicon is an excellent thermal conductor, so the temperature of the cross-beams quite far from the area immersed in the molten solder fountain, even up to a few tens of millimetres, will still be above solder liquidus temperature. The actual temperature profile of a solder joint electrical interconnect during the soldering process as a function of time depends on the molten solder temperature, the speed of traversal of the sub-assembly through the solder fountain, the width and depth and flow-rate of the molten solder in the fountain, the thermal mass and the thermal connectivity of sliver cells to the crossbeams, and the heat-sinking properties of the base clamp to which the raft, mesh raft, or boat sub-assembly is mounted during the wave-solder process.

In the case of plank solar cells, the requirements are slightly different because plank solar cells are substantially thicker, but the cross-beams may still be very thin, of the order of 50 μm to 100 μm. In this case, the thermal mass of the plank solar cell raft, mesh raft, or boat is still quite small, but not as small as for sliver solar cells. However, the thermal mass in the case of plank solar cells is effectively broken up into a consecutive sequence of very wide, but short, increments. Since silicon is an excellent thermal conductor, the applied heat from the solder fountain to the plank cells immersed in that fountain conducts along the cell away from the joint. In this case, the temperature profile along the plank cell away from the joint is still a function of time and distance, but a stronger function of time than is the case for sliver cells. These considerations still place a very strong emphasis on reducing time spent above solder liquidus temperature for plank cells, despite their significantly larger thermal mass.

Understanding the physics behind the local soldering point and the raft-wide thermal profile of the sliver cell raft, mesh raft, or boat sub-assembly and the plank cell raft, mesh raft, or boat sub-assembly as a function of time while the raft, mesh raft or boat is traversing the solder fountain is important for developing the soldering process. With conventional printed circuit board and electronics soldering, the pads and components are generally thermally isolated, with the thermal conduction proceeding predominantly through the fibreglass board, which is a poor conductor. Furthermore, problems associated with dissolving the pads, which are generally quite thick copper or tinned copper, at least where “thick” is understood in relation to the thickness of the metallised electrodes on plank cells or sliver cells, are not generally an issue. For these, and other reasons, a conventional approach to selective wave soldering of sliver solar cell and plank solar cell solder rafts, solder mesh rafts, and solder boats is not appropriate.

In order to establish the correct work-piece temperature profile as a function of time for devices such as rafts with very small thermal masses and high thermal conductivity, the process transport speeds are increased well beyond conventional soldering parameters. For example, a useful set of machine set-up parameters for selective wave soldering of raft, mesh raft, or boat sub-assemblies for machines similar to the EBSO range of selective wave soldering machines, is a flux setting of about 20% that required for conventional boards, an infra-red pre-heat period of approximately 30-50% that required for conventional components, and a transport speed approximately 6 times faster than for conventional selective wave solder applications, with a solder-bath temperature of 265° C., and the selective wave solder process conducted in a nitrogen atmosphere.

Specifically, the following selective wave solder process parameters are preferred:
(i) IR preheat 10-40 sec (and more preferably 20 sec);
(ii) transport speed 250-400 mm/sec (more preferably 340-360 mm/s);
(iii) solder temperature 250-280 C for 2% Ag Sn/Pb Eutectic solder) (more preferably 265 C);
(iv) Fountain height 3.2 mm through a 3.0 mm diameter nozzle;
(v) workpiece immersed 1.4 mm below top of free-standing fountain; and
(vi) the amount of flux deposited is not quantified by the EBSO selective wave soldering machines, but is set by the operator to be near the smallest reliably consistent delivery volume.

In the case of solder rafts, the end of the cross-beam is immersed in the solder fountain for between 0.4 to 0.6 second dwell time to commence the heating profile which precedes, by thermal conduction processes, the actual arrival of the solder fountain and hence solder on the pad and interconnects during the component transportation across the solder wave. This effective pre-heat time and the associated temperature profile of a solder site as a function of time, produced by thermal conduction along the cross-beams, and travelling in front of the soldering wave is mirrored by the cooling profile travelling behind the soldering wave can be controlled by the solder temperature, the solder flow rate, the effective volume of the solder fountain, the area of the fountain in contact with the raft solar cell members, the transport speed, the area and location of the raft, mesh raft, or boat which is in contact with the clamp, the thermal transfer properties of that contact, and the heat-sinking properties of the clamp.

Those skilled in the art will appreciate that the possible combinations of the above parameters provide a broad range of options from which a suitable manufacturing process, with a sufficiently large process window, can be selected.

Alternatively, the solder process can be performed using conventional wave soldering, provided that the foregoing requirements regarding speed, temperature, and time above liquidus are incorporated in the conventional solder wave environment. In this case, the entire raft assembly passes through the essentially horizontal solder wave, so the entire length of electrode and narrow cell is immersed at some time in solder. The raft, mesh raft, or boat is preferably oriented so that the sliver or plank solar cells are aligned with the direction of travel to reduce turbulence within the solder wave and prevent “shading” of component locations that need to be exposed to the solder wave. The advantage of this method is that the solar cell electrodes can be “plated up” in the same operation used to establish the electrical connections and provide the physical restraint and structure of the sub-assembly. Disadvantages include increased complexity of the operation, difficulty controlling the temperature profile of the sub-assembly, and difficulty controlling the quantity of solder deposited on the solar cell electrodes. Also, mainly arising from the temperature control issue, the elimination of “tails” and small droplets from the solder surfaces on the soldered sub-assembly can be a problem. Those skilled in the art will be aware that there are several approaches to minimise the effect of these difficulties.

FIG. 8 shows a detailed section of a solder raft sub-assembly 800, in this case constructed using sliver solar cells. The slivers 801 are selective wave soldered to the cross-beam 802 via the solder pads 803. The slivers are retained on the cross-beam solely by the solder connections 804 to the sliver electrodes 805 in the absence of any adhesive. The use of solder to establish electrical connections as well as to maintain the physical sub-assembly structure is a very important and valuable feature. This feature eliminates the need for several costly and time-consuming precision processing steps, such as stencilling or dispensing with their associated alignment and accuracy requirements, as well as eliminating the inclusion of non-conventional materials into the sub-assembly and solar module structure.

The precision steps eliminated include the stencilling or printing of a precise quantity of adhesive in a precise location on the cross-beam between the metallised pads. Precision in location and quantity is necessary in order to eliminate the possibility of the adhesive extruding, leaking, or wicking between the sliver and the cross-beam and interfering with the electrical connections. The adhesive must be a dielectric to prevent bridging. The second precision operation is the dispensing, stencilling or printing of a precise quantity of solder paste on the metallised pads. The solder paste is then reflowed to form the electrical connections. The application of the solder paste introduces further complications because of the presence of the adhesive.

Alternatively, the solder paste can be applied first—which introduces a problem for the application of the adhesive in the presence of the solder paste. The reflow operation must be carried out within certain time limits, depending on the requirements of the particular solder paste used, and the prepared sub-assemblies need to be stored under controlled conditions so the flux and paste are not degraded. Furthermore, a reflow operation attracts all the difficulties with time, temperature, and electrode dissolution discussed earlier.

The precision steps eliminated, illustrated above by way of example with a solder paste stencilling or dispensing process, also apply to alternative methods of providing electrical connection and physical restraint structures to the sub-module assemblies, such as conductive epoxy as detailed in International Patent Application No. PCT/AU2005/001193. All alternative methods to the solder wave process described herein involve some form of metering the volume, identifying the location, and depositing the measured quantity of material in place. The solder wave process performs all of these tasks “automatically” in an easily-controlled, rapid, reliable, repeatable, and cheap manner at low cost using cheap, conventional, reliable, and well-understood materials; with the added advantage of eliminating time-consuming process steps and expensive machines with attendant yield issues.

The solder wave process solves all the known problems of previous methods of assembly and electrical connection in forming sub-assemblies constructed from plank solar cells or sliver solar cells.

The design of the topology of the metallised pads is another important feature of the process. Control of the shape of the metallised pads, the area of the pads, and the relative area of sections of the pads, as well as the process parameters of solder temperature, speed, and flux type and quantity, which helps control the surface tension of the molten solder, can all be used to control the quantity and distribution of solder retained to form the electrical inter-connections and physical restraint for the solar cells in the sub-module assembly. The distribution and quantity of the solder in the solder joint 804 is important in order to achieve good electrical connection and good physical strength at the sliver edge. The solder joints 804 in the sample shown in FIG. 8 indicate good control of the solder distribution, with the solder beading at the edges of the sliver electrodes and forming good fillets with the electrode surface indicating good wetting of the solder joint. The vertical profile of the entire solder joint lies below the plane of the top surface of the slivers. This is important for minimising the thickness of the sliver sub-assembly and keeping the profile as planar as possible in order to minimise stresses introduced in the sub-assembly during lamination within the module. In the absence of these control mechanisms, the solder will tend to bead in the centre of the inter-connections, with excess solder. In this case it is very difficult to control the quantity of solder retained on the metallised pads, with excess solder aggravating the tendency since the surface tension of the beaded droplet works to attract more solder to the bead, increasing the size of the bead. This results in the profile of the solder protruding substantially above the top surface of the solar cell plane, and the stresses introduced during lamination can fracture the cross-beams causing failure, or weaken the cross-beams which leads to subsequent failure either during lamination or subsequent use of the module.

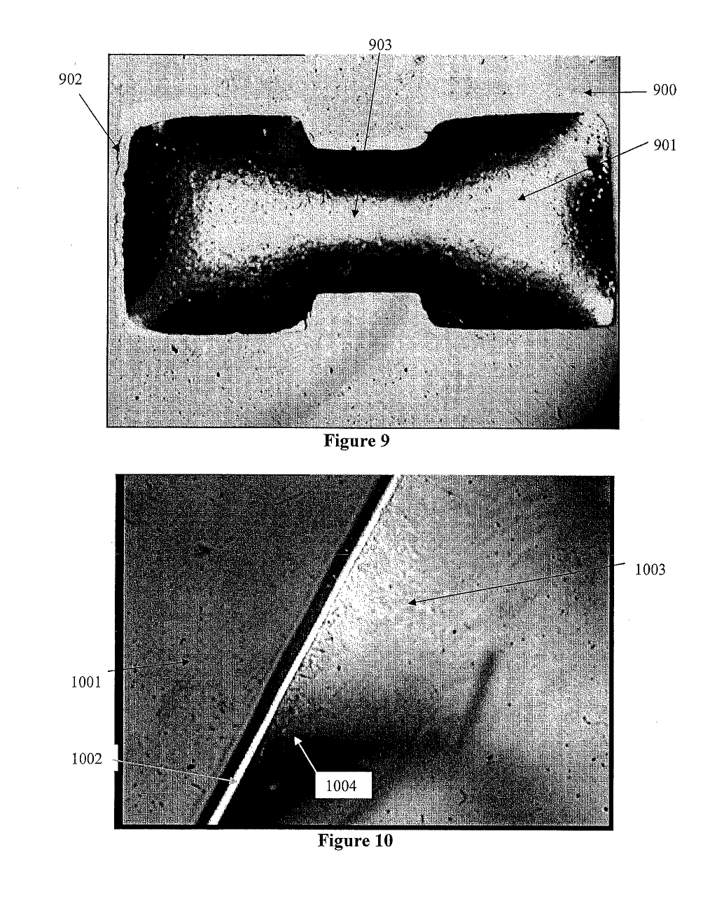

FIG. 9 is a plan view of soldered metallised pad 901 on a cross-beam 900. The pad is approximately 1.4 mm long, 0.4 mm wide at the ends, and 0.3 mm wide across the central region. The solder distribution, controlled by the pad shape and other parameters, described above, can be clearly seen. The solder operation was conducted in a nitrogen atmosphere, resulting in a clean surface 903. Higher magnification shows that the solder has a very small crystal structure; a result of the rapid cooling. The partial dissolution of the metallised pad, in this case silver over chromium, can be seen on the left hand edge 902. Dissolution in this area is mainly because the evaporated silver metal was thinner near this edge due to partial shadowing from the evaporation mask used during deposition.

Referring to FIG. 10, the solder joint of FIG. 8 is shown in more detail. The narrow solar cell 1001 and cell electrode 1002 are soldered to the cross-beam by the solder pad 1003 which cleanly wets the silver of the solar cell electrode, demonstrated by the fillet 1004. The image is about 0.15 mm wide and 0.1 mm high.

FIG. 11 shows a detailed cross-section of a soldered joint at the solar cell electrode. The solder 1101 rises to the level of the top of the cell electrode 1102. The solder also wets that area of the pad 1104 protruding under the solar cell 1105 along the cross-beam 1006. The solder completes the electrical interconnection as well as physically attaching the solar cell 1105 to the cross-beam 1106.

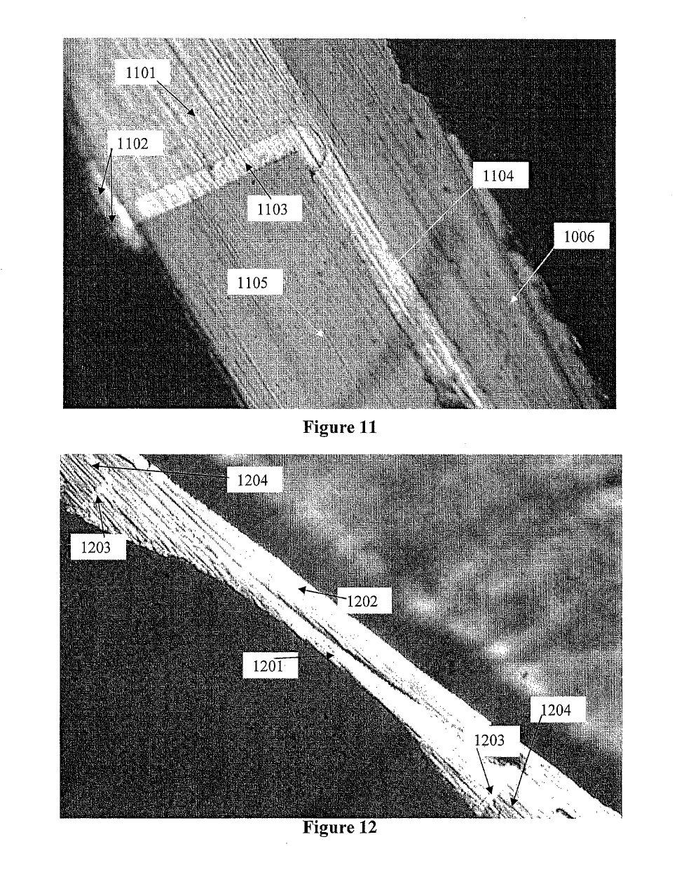

The samples shown in cross-section in FIG. 11 and FIG. 12 were prepared by slicing the cross-beam of a solder raft along its length in the middle of the solder pads using a diamond wheel dicing saw.

FIG. 12 shows the vertical profile of the cross-section of a solder interconnection 1201 on the cross-beam 1202. The solder thickness increases near the cell electrodes to cover the entire thickness of the electrodes 1203 on the edge of the solar cells 1204. Note that the solder profile remains below the plane of the top surface of the slivers at all times.

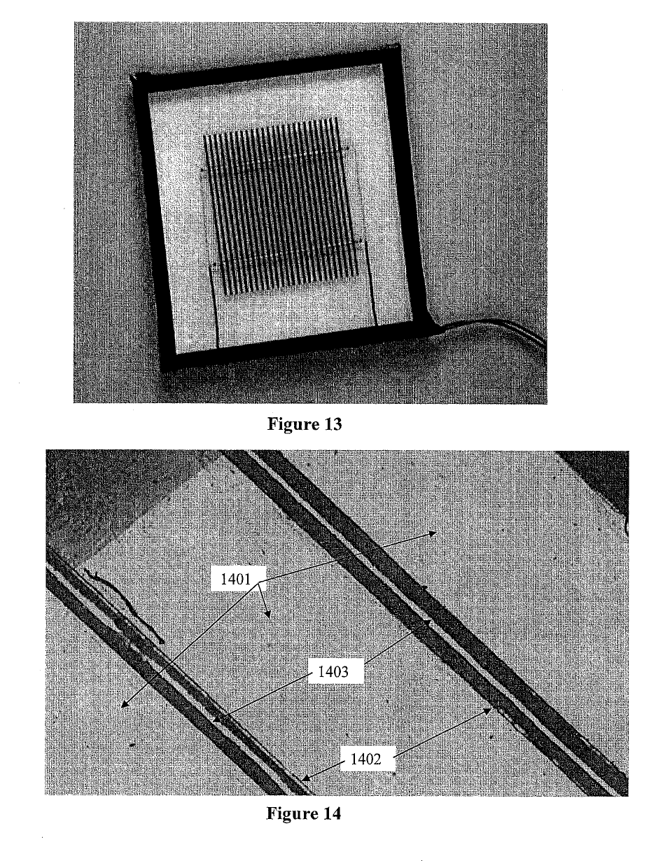

FIG. 13 shows a completed and functioning solder raft mini-module. The module is 100 mm square, with 26 slivers, 1 mm wide, 60 μm thick and 60 mm long connected in series. The module contains only conventional materials, namely solder for electrical connections and EVA for encapsulation, apart from the silicon solar cells and silicon cross-beams. The module has an aperture efficiency of 13%, with only 50% sliver solar cell coverage and an operating voltage around 15 V at MPP.

FIG. 14 is a high magnification plan view of a portion of a solder boat sub-module assembly. The narrow solar cells 1401 are electrically connected along the entire length of the electrodes 1402 running along the edge face of the sliver cell by a solder joint 1403. The solder joint 1403 also connects to a narrow metallised strip running the length of the solar cells along the substrate and aligned with the gap between the sliver electrodes. The metallised strip is formed in a manner similar to the process used to establish metallised pads on the cross-beams of solder rafts. The image shows a portion of a solder boat about 3 mm wide and 2 mm high.

The thickness of the solder bead in the solder boats can be controlled in a manner similar to that for solder rafts. Further, the electrical connection locations and lengths can be controlled either by the robotic translation stage of the selective wave solder machine, or by the position, presence, or absence of the metallised strip on the substrate. As a further variation, the solder can be directed under the edge of the solar cell in a manner similar to 1104 in FIG. 11 by extending the width of the metallisation on the substrate. These control methods are useful for “tuning” the heat-sink location and effectiveness for solder boats in concentrator applications. The thermal conductivity of the broadened solder pad under the solar cells can be yet further increased by metallising strips along the surface of the solar cell face by evaporating metal on the face up to, and even including, the solar cell electrodes. There is no danger of bridging the solar cell electrodes providing that the gap in the middle of the narrow solar cell, running the length of the cell lower face between the metallised areas running the length of the cell towards the electrode edges of the lower face, is sufficiently wide, does not overlap the metallised strips on the substrate, and does not allow cross-electrode solder bridging. Using this enhanced physical, thermal, and electrical connection method described herein, the strength of adhesion of narrow solar cells to the substrate, the thermal conductivity of these cells to the heat sink, and the electrical conductivity requirements of the sub-module assembly can be enhanced for any solder boat application, including sliver solar cell solder boats and plank solar cell solder boats for concentrator receiver applications.

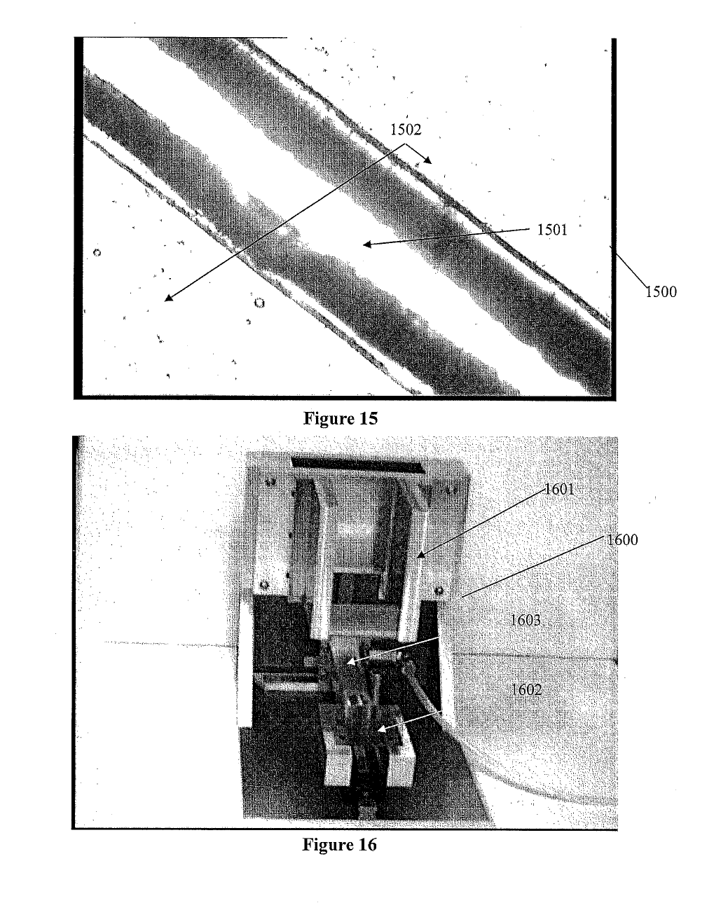

FIG. 15 shows a highly magnified plan view of a portion of a solder electrical connection 1501 between two elongate solar cells 1502 on a solder boat. The image shows a portion of the solder boat 1500 about 0.4 mm wide and 0.3 mm high. The solder joint 1501 between the two adjacent solar cells is approximately 0.1 mm wide. If the joint is substantially narrower, it is difficult to perform the complete solder process in a single operation because the viscosity of the solder prevents the solder from the selective wave solder fountain penetrating the gap and wetting the metallised surface on the substrate.

However, the joint can be made much narrower by using a two-step soldering process wherein the tracks on the substrate are pre-tinned in the first step. In this case, the selective wave solder deposits solder on the outer surface of the boat sub-module slivers, that is the surface of the electrode near the face of the solar cell oriented towards the solder fountain, which then wets the electrode surface and wicks by capillary action to the rear surface of the solar cell where it makes contact with and alloys to the solder on the tinned tracks of the substrate. In this case, it is capillary action, rather than reduced solder viscosity controlled by heat and solder surface tension reduction controlled by flux, that is utilised to introduce solder through a small gap. However, the reduction in surface tension by use of appropriate flux and a nitrogen atmosphere does facilitate initiating the capillary action by ensuring the thorough wetting by the solder of the outer region of the electrode.

Problems with sub-module assembly stresses caused by differential expansion due to differing coefficients of thermal expansion between the solder and the silicon can be reduced or eliminated by shortening the length of the solder runs along the solar cell electrodes. For example, instead of running the entire length of the electrode, the solder run can be broken into a collection of short runs by placing the metallisation on the substrate in the form of a “dashed line” or by creating gaps in the metallised electrode on the edge of the solar cell, or by a combination of these two approaches. Alternatively, for example, the continuous line connection could be implemented as a “dotted line” where the dots are separated by some distance along the length of the cell. In this case, the electrical, physical and thermal connections occupy some fraction of the length of the narrow solar cell.

In other cases, the electrical connections between the cell electrodes can be more frequent than the thermal and physical connections to the substrate by, for example, not having a metallised area on the substrate in the region where electrical connection was desired between the cells, but physical and thermal connection is not required. There are many variations possible.

Referring to FIG. 16, which is a bench-top multi-stack cassette, the process for forming raft sub-assemblies can be described. The vacuum head 1603, shown in more detail in FIG. 17, engages the bottom plane of the elongate cells held in a planar array in the slots or grooves of a multi-stack cassette 1601. The vacuum is turned on, and the vacuum head 1603 retracts vertically downwards, removing the array of narrow cells which is then deposited on the cross-beam support structure 1701. Both the vacuum head 1603 and cross-beam support 1701 translate on respective linear translation stages set at right angles to one another, the linear translation stage 1703 for the cross-beam support being visible in FIG. 17. After the elongate cell array is deposited on the cross-beams, the vacuum head 1603 retracts further downwards until the assembly clears the top surface of the vacuum head. The cross beam support structure 1701 is then moved forwards so that the elongate cell array 100 can be removed and transferred to a clamp for subsequent solder processing.

The process described above provide electrical interconnection and physical structure restraints for a plurality of elongate solar cells assembled in the form of rafts, mesh rafts, and boats, the formation and assembly of which has been described in International Patent Application No. PCT/AU2005/001193. The resulting structures are referred to herein as solder rafts, solder mesh rafts, and solder boats.

In particular, these allow the assembly, electrical connectivity, and means of establishing the physical structure of a plurality of thin and/or narrow, elongate solar cells to form a sub-assembly with a significant reduction in the number of steps required for present state of the art sliver or plank elongate solar cell assembly, and with all methods, procedures, and products formed without requiring the introduction or use of any adhesives or non-conventional materials into the sub-assembly and hence subsequently into a corresponding solar module.

The methods, structures, and processes described herein maintain the orientation and polarity of elongate solar cells during sub-module assembly, provide significant simplification of the elongate solar cell sub-assembly handling and processing, subsequent photovoltaic module assembly processes, produce easily handled solder raft, solder mesh raft, and solder boat sub-modules with a greatly reduced number of individual assembly and processing steps required, allows the easy use of conventional photovoltaic module assembly equipment for handling and stringing solder rafts, solder mesh rafts, and solder boats, and allows the use of solely conventional photovoltaic module materials in manufacturing sliver solar cell modules and narrow-cell solar modules.

The processes described above can utilise a wide range of solder specifications, such as low melting point tin/lead solder, high melting point tin/lead solder, eutectic solder alloys, lead/tin/silver solder, the entire range of conventional lead-free solders, and also non-conventional zinc/tin, antimony or indium or bismuth lead-free alloys for example.

More importantly, the processes are also suitable for new-generation lead-free solders which will be required in the EC after 1 Jul., 2006. Further, the processes can also be used to form the electrical interconnections between sub-module assemblies, groups of sub-module assemblies, sub-module assemblies and bus-bar interconnects, and also bus-bar to bus-bar interconnections which are required in order to form photovoltaic devices into solar power modules.

Many modifications will be apparent to those skilled in the art without departing from the scope of the present invention as hereinbefore described with reference to the accompanying drawings.

What is claimed is:

1. A solar cell interconnection process for forming a solar cell sub-module for a photovoltaic device, the process including the steps of: mounting a plurality of elongate solar cells in a structure that maintains the elongate solar cells in a substantially longitudinally parallel and generally co-planar configuration; and establishing one or more conductive pathways extending through the structure to electrically interconnect the elongate solar cells; wherein the one or more conductive pathways are established by wave soldering.

2. The process of claim 1, wherein the one or more conductive pathways are established by selective wave soldering.

3. The process of claim 2, including mounting the elongate solar cells to a thermally compatible support to prevent damage to the elongate solar cells or the one or more conductive pathways during a change in temperature.

4. The process of claim 3, wherein the elongate solar cells and the one or more conductive pathways form the structure.

5. The process of claim 4, wherein the one or more conductive pathways electrically interconnect the elongate solar cells in series to increase the output voltage of the solar cell sub-module.

6. The process of claim 5, wherein the one or more conductive pathways electrically interconnect the elongate solar cells in parallel to reduce the effect of shadowing on output of the sub-module.

7. The process of claim 6, wherein the one or more conductive pathways electrically interconnect the elongate solar cells in groups electrically interconnected in parallel, with the elongate solar cells in each group being electrically interconnected in series.

8. The process of claim 7, wherein the mounted elongate solar cells abut one another.

9. The process of claim 8, wherein the elongate solar cells are mutually spaced.

10. The process of claim 9, wherein each of the elongate solar cells includes two active faces, and a spacing between elongate solar cells is selected on the basis of illumination of the active faces of the elongate solar cells and the number of elongate solar cells in the sub-module.

11. The process of claim 10, wherein the structure includes at least one support to which the elongate solar cells are mounted.

12. The process of claim 11, including forming metallised regions on said at least one support, the shape of the metallised regions being adapted to retain solder predominantly at ends of each metallised region.

13. The process of claim 12, wherein the shape of each metallised region includes end regions disposed about a central region, the areas of the ends regions being substantially greater than the area of the central region.

14. The process of claim 13, wherein each metallised region has a substantially I-beam or dog-bone shape.

15. The process of claim 14, wherein said step of mounting includes arranging the plurality of elongate solar cells so that electrodes of adjacent ones of the elongate solar cells are substantially located at respective ends of corresponding metallised regions.

16. The process of claim 15, wherein the step of establishing one or more conductive pathways includes applying a selective solder wave fountain to each metallised region to interconnect electrodes of adjacent ones of the elongate solar cells, the solder deposited by the selective solder wave fountain forming beads substantially at said electrodes.

17. The process of claim 16, wherein the at least one support is compliant to accommodate thermal expansion of the elongate solar cells.

18. The process of claim 17, including encapsulating the structure within a transparent encapsulating material.

19. The process of claim 18, wherein the structure includes one or more crossbeams to which the elongate solar cells are mounted.

20. The process of claim 19, including forming metallised regions on said one or more crossbeams, the shape of the metallised regions being adapted to retain solder predominantly at ends of each metallised region.

21. The process of claim 20, wherein the shape of each metallised region includes end regions disposed about a central region, the areas of the ends regions being substantially greater than the area of the central region.

22. The process of claim 21, wherein each metallised region has a substantially I-beam or dog-bone shape.

23. The process of claim 22 wherein said step of mounting includes arranging the plurality of elongate solar cells so that electrodes of adjacent ones of the elongate solar cells are substantially located at respective ends of corresponding metallised regions.

24. The process of claim 23, wherein the step of establishing one or more conductive pathways includes applying a selective solder wave fountain to each metallised region to interconnect electrodes of adjacent ones of the elongate solar cells, the solder deposited by the selective solder wave fountain forming beads substantially at said electrodes.

25. The process of claim 24, wherein the one or more crossbeams are silicon.

26. The process of claim 24, wherein the one or more crossbeams include a polymer, a ceramic, a metal or a glass.

27. The process of claim 26, wherein a size of the structure is selected to be substantially the same as a corresponding size of a standard solar cell.

28. The process of claim 27, wherein said step of mounting includes mounting the elongate solar cells on an electrically insulating continuous or semicontinuous support.

29. The process of claim 28, wherein the one or more conductive pathways are formed on the electrically insulating support.

30. The process of claim 29, wherein the electrically insulating support is substantially silicon.

31. The process of claim 29, wherein the electrically insulating support is substantially borosilicate glass, plastic, or ceramic.

32. The process of claim 31, wherein the support is mounted to a heat sink.

33. The process of claim 32, wherein the support has substantial thermal conductivity and acts as a heat sink.

34. The process of claim 33, wherein the elongate solar cells and the one or more conductive pathways substantially form the structure.

35. The process of claim 34, including mounting a reflector behind the solar cell sub-module to reflect light passing through gaps between the elongate solar cells back towards the elongate solar cells to improve the efficiency of the photovoltaic device.

36. The process of claim 35, wherein each of the elongate solar cells includes electrically conductive contacts on at least two adjacent surfaces of the solar cell, and the one or more conductive pathways include substantially planar electrically conductive regions that are mounted to the electrically conductive contacts of the elongate solar cells, thereby electrically interconnecting the elongate solar cells.

37. The process of claim 36, including mounting a sheet of pliant material to the structure to provide a resilient solar cell sub-module.

38. The process of claim 37, including conformally mounting the solar cell sub-module to a substantially rigid curved support to provide a curved solar cell sub-module.

39. The process of claim 38, including conformally mounting the structure to a substantially rigid planar support and deforming the resulting assembly to provide a non-planar solar cell sub-module.

40. The process of claim 39, wherein the substantially rigid support is transparent.

41. The process of claim 38, wherein the substantially rigid curved support is glass.

42. The process of claim 38, wherein the substantially rigid curved support is a curved extruded aluminium receiver for a linear concentrator.

43. The process of claim 42, including processing at least a portion of one or more faces of each of the elongate solar cells in the solar cell sub-module.

44. The process of claim 43, wherein said processing includes depositing a coating on at least a portion of the one or more faces.

45. The process of claim 44, wherein said coating includes at least one of an anti-reflection coating, a passivation coating, and metallisation.

46. The process of claim 45, including mounting a plurality of the solar cell sub-modules in a linear concentrator system.

47. The process of claim 46, wherein the one or more conductive pathways electrically connect the elongate solar cells in series so that the electrical current generated by the elongate solar cells flows substantially in a direction parallel to the longitudinal axis of the linear concentrator system to reduce the series resistance of the elongate solar cells.

48. The process of claim 47, wherein the mounting of the sub-modules includes arranging the solar cell sub-modules in closely adjacent rows mounted to a receiver of the linear concentrator system, the rows being parallel to an optical axis of the receiver.

49. The process of claim 48, wherein the linear concentrator system includes a thermally conducting substrate having a first portion located near an optical axis of the system and a second portion, the mounting of the sub-modules being such that the elongate solar cells are mounted substantially adjacent to each other on the first portion of the thermally conducting substrate, the second portion of the thermally conducting substrate being actively cooled in so that heat generated by the elongate solar cells is conducted away from the elongate solar cells in a direction substantially perpendicular to the optical axis of the system.

50. The process of claim 49, wherein said step of establishing one or more conductive pathways includes immersing electrodes of said elongate solar cells in molten solder for a period less than one second.

51. The process of claim 50, wherein said period is at least about 0.3 seconds and at most about 0.5 seconds.

52. The process of claim 51, wherein an end of a crossbeam of said sub-module is immersed in molten solder for a period of about 0.4 to 0.6 seconds prior to immersing said electrodes.

53. The process of claim 52, further including forming electrodes on edges of the elongate solar cells, said step of forming including: depositing an electrically conductive layer on edges of the elongate solar cells; and dipping the elongate solar cells into a molten bath of solder to coat the electrically conductive layer with a layer of solder.

54. The process of claim 53, including forming a plurality of elongate substrates from a wafer, and forming said elongate solar cells from respective ones of said elongate substrates.

55. The process of claim 54, wherein active faces of said elongate solar cells are formed on faces of said elongate substrates formed perpendicular to a planar surface of said wafer.

56. The process of claim 54, wherein active faces of said elongate solar cells are formed on faces of said elongate substrates corresponding to respective regions of a planar surface of said wafer.

57. The process of claim 56, including forming an electrical interconnection between the solar cell sub-module and another sub-module by wave soldering.

58. The process of claim 57, including forming an electrical interconnection between the solar cell sub-module and a busbar of the photovoltaic device by wave soldering.

59. The process of claim 58, including forming an electrical interconnection between busbars of the photovoltaic device by wave soldering.

60. The process of claim 59, wherein the wave soldering includes selective wave soldering.

61. A solar cell sub-module formed by claim 1.

62. A photovoltaic device including a plurality of solar cell sub-modules formed by claim 1.
